(19) United States
(12) Patent Application Publication
(10) Pub. No.: US 2026/0107516 A1
(43) Pub. Date: Apr. 16, 2026

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Masahiro WATABE, Tokyo (JP)

(73) Assignee: Japan Display Inc., Tokyo (JP)

(21) Appl. No.: 19/358,596

(22) Filed: Oct. 15, 2025

(30) Foreign Application Priority Data
Oct. 15, 2024 (JP) 2024-180259
Aug. 22, 2025 (JP) 2025-139085

(51) Int. Cl. H10D 30/67

(52) U.S. Cl. CPC H10D 30/6755; H10D 30/6736

(57) ABSTRACT

A semiconductor device according to an embodiment of the present invention includes: a first gate electrode; a first gate insulating layer above the first gate electrode; an oxide semiconductor layer above the first gate insulating layer and including a channel portion and a conductive portion; second and third gate insulating layers above the oxide semiconductor layer; and a second gate electrode above the third gate insulating layer, wherein the semiconductor device includes a first region overlapping the channel portion in a plan view and a second region overlapping the conductive portion in the plan view, an amount of impurities included in the conductive portion is more than an amount of the impurities included in the channel portion, the second gate insulating layer in the second region included the impurities, and the third gate insulating layer in the second region does not include the impurities.

### CROSS REFERENCE TO RELATED APPLICATIONS

This application claims the benefit of priority to Japanese Patent Application No. 2024-180259, filed on Oct. 15, 2024 and Japanese Patent Application No. 2025-139085, filed on Aug. 22, 2025, the entire contents of which are incorporated herein by reference.

### FIELD

An embodiment of the present invention relates to a semiconductor device and a display device.

In recent years, as a material forming a semiconductor device, an oxide semiconductor has attracted attention instead of amorphous silicon, polysilicon, and single crystal silicon. In particular, as a semiconductor device including an oxide semiconductor, a thin film transistor using an oxide semiconductor as a channel has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405.) Similar to a semiconductor device using amorphous silicon as a channel, a thin film transistor using an oxide semiconductor as a channel can be formed through a simple structure and a low-temperature process. It is known that a thin film transistor using an oxide semiconductor as a channel has a higher field-effect mobility than a thin film transistor using amorphous silicon as a channel.

### SUMMARY

A semiconductor device according to an embodiment of the present invention includes: a first gate electrode above an insulating surface; a first gate insulating layer above the first gate electrode; an oxide semiconductor layer above the first gate insulating layer and including a channel portion and a conductive portion having lower resistance than the channel portion; a second gate insulating layer above the oxide semiconductor layer; a third gate insulating layer above the second gate insulating layer; and a second gate electrode above the third gate insulating layer, wherein the semiconductor device includes a first region overlapping the channel portion in a plan view and a second region overlapping the conductive portion in the plan view, an amount of impurities included in the conductive portion is more than an amount of the impurities included in the channel portion, the second gate insulating layer in the second region includes the impurities, and the third gate insulating layer in the second region does not include the impurities.

A semiconductor device according to an embodiment of the present invention includes: a first gate electrode above an insulating surface; a first gate insulating layer above the first gate electrode; an oxide semiconductor layer above the first gate insulating layer and including a channel portion and a conductive portion having lower resistance than the channel portion; a second gate insulating layer above the oxide semiconductor layer; a third gate insulating layer above the second gate insulating layer; and a second gate electrode above the third gate insulating layer, wherein the semiconductor device includes a first region overlapping the channel portion in a plan view and a second region overlapping the conductive portion in the plan view, an amount of impurities included in the conductive portion is more than an amount of the impurities included in the channel portion, and in the second region, an average concentration of the impurities in a thickness direction of the second gate insulating layer is 100 times or more than an average concentration of the impurities in the thickness direction of the third gate insulating layer.

A semiconductor device according to an embodiment of the present invention includes: a first gate electrode above an insulating surface; a first gate insulating layer above the first gate electrode; an oxide semiconductor layer above the first gate insulating layer and including a channel portion and a conductive portion having lower resistance than the channel portion; a second gate insulating layer above the oxide semiconductor layer; a third gate insulating layer above the second gate insulating layer; and a second gate electrode above the third gate insulating layer, wherein the semiconductor device includes a first region overlapping the channel portion in a plan view and a second region overlapping the conductive portion in the plan view, an amount of impurities included in the conductive portion is more than an amount of the impurities included in the channel portion, and in a vicinity of a boundary between the second gate insulating layer and the third gate insulating layer in the second region, a concentration of the impurities included in the second gate insulating layer is 100 times or more than a concentration of the impurities included in the third gate insulating layer.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is a sequence diagram showing a method for manufacturing a semiconductor device according to an embodiment of the present invention.

FIG. 4 is a schematic cross-sectional view showing a method for manufacturing a semiconductor device according to an embodiment of the present invention.

FIG. 5 is a schematic cross-sectional view showing a method for manufacturing a semiconductor device according to an embodiment of the present invention.

FIG. 6 is a schematic cross-sectional view showing a method for manufacturing a semiconductor device according to an embodiment of the present invention.

FIG. 7 is a schematic cross-sectional view showing a method for manufacturing a semiconductor device according to an embodiment of the present invention.

FIG. 8 is a schematic cross-sectional view showing a method for manufacturing a semiconductor device according to an embodiment of the present invention.

FIG. 9 is a schematic cross-sectional view showing a method for manufacturing a semiconductor device according to an embodiment of the present invention.

FIG. 10 is a schematic cross-sectional view showing a method for manufacturing a semiconductor device according to an embodiment of the present invention.

FIG. 11 is a schematic cross-sectional view showing a method for manufacturing a semiconductor device according to an embodiment of the present invention.

FIG. 12 is a schematic cross-sectional view showing a method for manufacturing a semiconductor device according to an embodiment of the present invention.

FIG. 13 is a schematic cross-sectional view showing a method for manufacturing a semiconductor device according to an embodiment of the present invention.

FIG. 14 is a schematic cross-sectional view showing a method for manufacturing a semiconductor device according to an embodiment of the present invention.

FIG. 15 is a schematic cross-sectional view showing a method for manufacturing a semiconductor device according to an embodiment of the present invention.

FIG. 16 is a schematic cross-sectional view showing a configuration of a semiconductor device according to an embodiment of the present invention.

FIG. 17 is a schematic cross-sectional view showing a configuration of a semiconductor device according to an embodiment of the present invention.

FIG. 18 is a schematic cross-sectional view showing a configuration of a semiconductor device according to an embodiment of the present invention.

FIG. 19 is a sequence diagram showing a method for manufacturing a semiconductor device according to an embodiment of the present invention.

FIG. 20 is a schematic cross-sectional view showing a method for manufacturing a semiconductor device according to an embodiment of the present invention.

FIG. 21 is a schematic cross-sectional view showing a configuration of a semiconductor device according to an embodiment of the present invention.

FIG. 22 is a schematic cross-sectional view showing a method for manufacturing a semiconductor device according to an embodiment of the present invention.

FIG. 23 is a schematic cross-sectional view showing a configuration of a semiconductor device according to an embodiment of the present invention.

FIG. 24 is a sequence diagram showing a method for manufacturing a semiconductor device according to an embodiment of the present invention.

FIG. 25 is a schematic cross-sectional view showing a method for manufacturing a semiconductor device according to an embodiment of the present invention.

FIG. 26 is a schematic cross-sectional view showing a method for manufacturing a semiconductor device according to an embodiment of the present invention.

FIG. 27 is a schematic cross-sectional view showing a method for manufacturing a semiconductor device according to an embodiment of the present invention.

FIG. 28 is a schematic cross-sectional view showing a method for manufacturing a semiconductor device according to an embodiment of the present invention.

FIG. 29 is a schematic cross-sectional view showing a configuration of a semiconductor device according to an embodiment of the present invention.

FIG. 30 is a schematic cross-sectional view showing a configuration of a semiconductor device according to an embodiment of the present invention.

FIG. 31 is a schematic cross-sectional view showing a configuration of a semiconductor device according to an embodiment of the present invention.

FIG. 32 is a sequence diagram showing a method for manufacturing a semiconductor device according to an embodiment of the present invention.

FIG. 33 is a schematic cross-sectional view showing a method for manufacturing a semiconductor device according to an embodiment of the present invention.

FIG. 34 is a schematic cross-sectional view showing a method for manufacturing a semiconductor device according to an embodiment of the present invention.

FIG. 35 is a schematic cross-sectional view showing a method for manufacturing a semiconductor device according to an embodiment of the present invention.

FIG. 36 is a schematic plan view showing an overall configuration of a display device according to an embodiment of the present invention.

FIG. 37 is a block diagram showing a circuit configuration of a display device according to an embodiment of the present invention.

FIG. 38 is a circuit diagram showing a configuration of a pixel circuit of a display device according to an embodiment of the present invention.

FIG. 39 is a cross-sectional view showing a configuration of a pixel of a display device according to an embodiment of the present invention.

FIG. 40 is a diagram showing a region where an impurity concentration was evaluated in a semiconductor device according to an embodiment of the present invention.

FIG. 41 is a diagram showing evaluation results of an impurity concentration of a semiconductor device according to an embodiment of the present invention.

### DESCRIPTION OF EMBODIMENTS

Hereinafter, embodiments of the present invention will be described with reference to the drawings. The following disclosure is merely an example. A configuration that can be easily conceived by a person skilled in the art by appropriately changing a configuration of an embodiment while keeping the gist of the invention is naturally included in the scope of the present invention. In order to make the description clearer, the drawings may schematically show the width, thickness, shape, and the like of each part in comparison with an actual embodiment. However, the illustrated shapes are merely examples, and do not limit the interpretation of the present invention. In the present specification and the drawings, the same reference signs are given to elements similar to those described above with respect to the drawings described above, and detailed description thereof may be omitted as appropriate.

In each embodiment of the present invention, a direction from a substrate toward an oxide semiconductor layer is referred to as “upper” or “above.” Conversely, a direction from the oxide semiconductor layer toward the substrate is referred to as “under” or “lower.” As described above, for convenience of explanation, although the term “above” or “below” will be used for description, for example, the vertical relationship between the substrate and the oxide semiconductor layer may be opposite to that shown in the drawings. In the following description, for example, the expression “oxide semiconductor layer above the substrate” merely describes the vertical relationship between the substrate and the oxide semiconductor layer as described above, and other members may be arranged between the substrate and the oxide semiconductor layer.

A “display device” refers to a structure that displays an image using an electro-optical layer. For example, the term “display device” may refer to a display panel including an electro-optical layer or may refer to a structure in which another optical member (for example, a polarizing member, a backlight, a touch panel, or the like) is attached to a display cell. The “electro-optical layer” may include a liquid crystal layer, an electroluminescent (EL) layer, an electrochromic (EC) layer, or an electrophoretic layer, as long as there is no technical contradiction. Therefore, although an organic EL display device including an organic EL layer is exemplified as a display device in the embodiments described later, the structure in the present embodiment can be applied to a display device including other electro-optical layers described above, such as a liquid crystal display device including a liquid crystal layer.

In the present specification, the expressions “α includes A, B or C,” “α includes any of A, B and C,” and “α includes one selected from a group consisting of A, B, and C” do not exclude the case where α includes a plurality of combinations of A to C unless otherwise specified. Furthermore, these expressions do not exclude the case where α includes other elements.

In the present specification, “coincide” means both “substantially coincide” as well as “perfectly coincide.” “Substantially coincide” refers to the case that falls within a range of small differences that do not perfectly coincide but can be considered as coincident, for example, within an error range of ±5% (preferably ±3%).

Conventionally, although various device structures including a top gate type structure and a bottom gate type structure have been studied for a thin film transistor using an oxide semiconductor, there are several problems in terms of reliability. For example, in the conventional device structure, it is difficult to achieve both securing withstand voltage characteristics of a gate insulating layer (specifically, a resistance against a high voltage applied between a gate and a source or between the gate and a drain) and suppressing damage to the oxide semiconductor layer. Therefore, there is still room for improvement in the reliability of a thin film transistor using a conventional oxide semiconductor.

An object of the present invention is to improve the reliability of a semiconductor device including an oxide semiconductor.

### 1. First Embodiment

A semiconductor device according to an embodiment of the present invention will be described by exemplifying a thin film transistor. For example, the semiconductor device of the embodiment described below may be an integrated circuit (IC), such as a microprocessor (Micro-Processing Unit: MPU), or a thin film transistor used in a memory circuit, in addition to a thin film transistor used in a display device (for example, an organic EL display device or a liquid crystal display device).

### 1-1. Configuration of Semiconductor Device

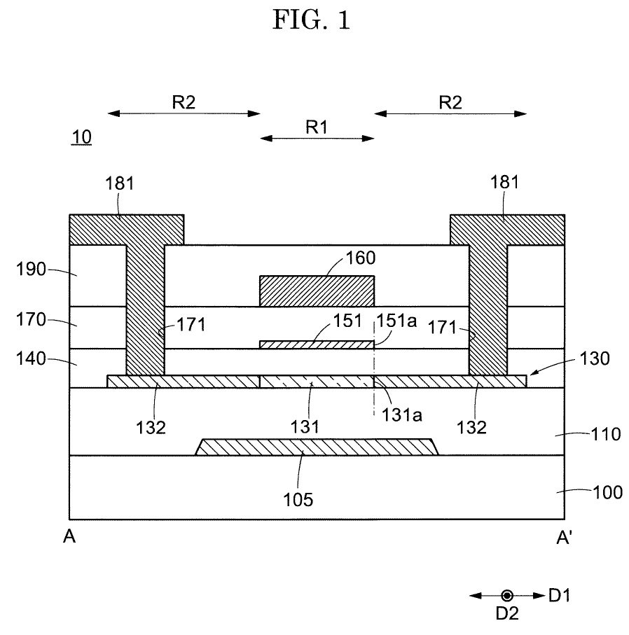

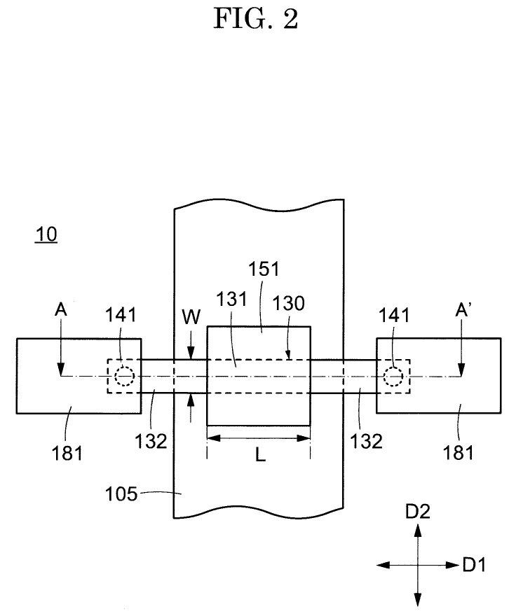

A A configuration of a semiconductor device 10 according to an embodiment of the present invention will be described. FIG. 1 is a schematic cross-sectional view showing a configuration of the semiconductor device 10 according to an embodiment of the present invention. FIG. 2 is a schematic plan view showing a configuration of the semiconductor device 10 according to an embodiment of the present invention. Specifically, FIG. 1 is a cross-sectional view taken along the dash-dot line shown by A-A′ shown in FIG. 2.

First, a cross-sectional structure of the semiconductor device 10 will be described with reference to FIG. 1. As shown in FIG. 1, the semiconductor device 10 is provided above a substrate 100. The semiconductor device 10 includes a gate electrode 105, a gate insulating layer 110, an oxide semiconductor layer 130, an insulating layer 140, a metal oxide layer 151, an insulating layer 170, a gate electrode 160, an insulating layer 190, and a terminal electrode 181.

The gate electrode 105 is provided on the substrate 100. The gate electrode 105 functions as a gate of the semiconductor device 10 (thin film transistor). Specifically, the gate electrode 105 has a function of applying a gate voltage to a channel portion 131 of the oxide semiconductor layer 130, which will be described later. An insulating layer (not shown) may be provided on the substrate 100. That is, the gate electrode 105 may be arranged directly or indirectly on the substrate 100. In other words, the gate electrode 105 is provided on an insulating surface.

The gate insulating layer 110 is provided on the substrate 100 and the gate electrode 105. The gate insulating layer 110 has a function as a barrier film for shielding impurities diffusing from the substrate 100 toward the oxide semiconductor layer 130, and a function as a base of the oxide semiconductor layer 130 arranged above.

Although not shown, in the present embodiment, the gate insulating layer 110 has a two-layer structure. Specifically, a silicon nitride layer is used as an insulating layer on the lower layer side of the gate insulating layer 110 (a side closer to the substrate 100) and a silicon oxide layer is used as an insulating layer on the upper layer side of the gate insulating layer 110 (a side closer to the oxide semiconductor layer 130). In the present embodiment, since the thickness of the insulating layer (silicon nitride layer) on the lower layer side is 200 nm and the thickness of the insulating layer (silicon oxide layer) on the upper layer side is 100 nm, the thickness of the gate insulating layer 110 is 300 nm. That is, in the present embodiment, the thickness of the gate insulating layer 110 can be set to 200 nm or more (preferably 300 nm or more, more preferably 400 nm or more). The gate insulating layer 110 may have a single-layer structure or a structure of three or more layers.

The oxide semiconductor layer 130 is provided on the gate insulating layer 110. The oxide semiconductor layer 130 includes the channel portion 131 and a conductive portion 132 that are contiguous in a direction D1. The channel portion 131 functions as a channel region of the semiconductor device 10. The conductive portion 132 functions as a source region or drain region of the semiconductor device 10. The conductive portion 132 is a region having a lower resistance than the channel portion 131, and has a function of transmitting carriers flowing through the channel portion 131 to the terminal electrode 181. Although details will be described later, the conductive portion 132 contains impurities (e.g., phosphorus, boron, argon, etc.) to reduce the resistance of the oxide semiconductor layer 130. On the other hand, the channel portion 131 does not contain the impurities. In other words, the amount of impurities contained in the conductive portion 132 is greater than the amount of impurities contained in the channel portion 131.

In this case, the expression “does not contain the impurities” means that no impurities are intentionally added, and does not mean that there are no impurities. For example, the expression “does not contain the impurities” means that when an SIMS (Secondary Ion Mass Spectrometry) analysis is performed on a certain layer, the impurity concentration calculated by the SIMS analysis in the layer is the detection limit, or the difference from the detection limit is one order or less of magnitude. For example, in the SIMS analysis for detecting boron, when the detection limit of boron is 10¹⁶ atoms/cm³, the layers where the boron concentration calculated by the SIMS analysis is 10¹⁷ atoms/cm³ or less can be said to “not contain boron.” The insulating layer 140 is provided on the oxide semiconductor layer 130. In the present embodiment, a silicon oxide layer is used as the insulating layer 140. The insulating layer 140 is a dielectric layer that electrically insulates a layer in which the gate electrode 160 described later is formed or a layer in which the terminal electrode 181 is formed and a layer in which the oxide semiconductor layer 130 is formed. The thickness of the insulating layer 140 is 50 nm or more and 200 nm or less (preferably 50 nm or more and 150 nm or less, more preferably 100 nm or more and 150 nm or less). The thickness of the insulating layer 140 is smaller than the thickness of the gate insulating layer 110. Advantages of the thin insulating layer 140 will be described later.

As shown in FIG. 1, a region that overlaps the channel portion 131 in a plan view is referred to as a first region R1, and a region that overlaps the conductive portion 132 in a plan view is referred to as a second region R2. Although details will be described later, the insulating layer 140 in the first region R1 does not contain an impurity for reducing the resistance of the oxide semiconductor layer 130, and the insulating layer 140 in the second region R2 contains the impurity. On the other hand, in both the first region R1 and the second region R2, the insulating layer 170 does not contain the impurity. That is, in the second region R2, the insulating layer 140 contains the impurity, but the insulating layer 170 does not contain the impurity. As will be described later, this configuration is caused by the timing at which the impurity is added.

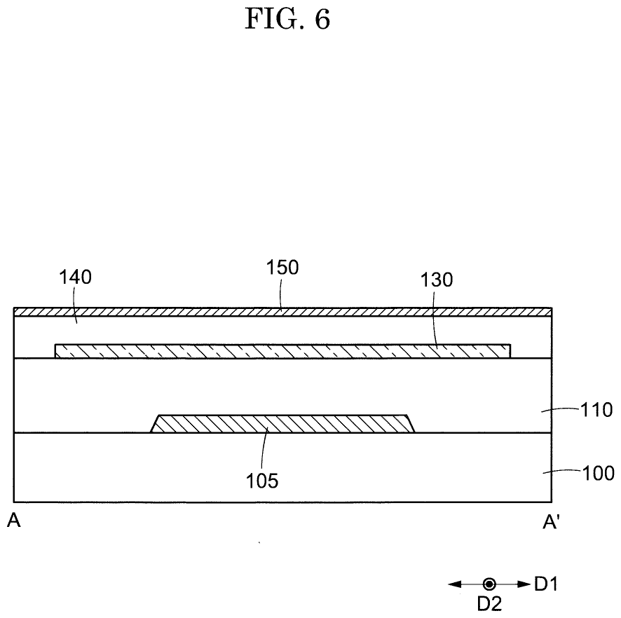

The metal oxide layer 151 is provided on the insulating layer 140. The metal oxide layer 151 of the present embodiment is composed of a metal oxide containing aluminum as a main component (containing aluminum). The metal oxide layer 151 is obtained by patterning the metal oxide layer into an island shape. The metal oxide layer 151 functions as a barrier layer that suppresses hydrogen diffused from above from reaching the channel portion 131 of the oxide semiconductor layer 130. Although details will be described later, the metal oxide layer 151 is a layer in which the metal oxide layer 150 (see FIG. 6) used in a heat treatment for supplying oxygen to the oxide semiconductor layer 130 is patterned in a manufacturing process of the semiconductor device 10. The thickness of the metal oxide layer 151 is 5 nm or more and 100 nm or less, 5 nm or more and 50 nm or less, 5 nm or more and 30 nm or less, or 7 nm or more and 15 nm or less.

The metal oxide layer 151 is arranged above the oxide semiconductor layer 130 via the insulating layer 140. That is, the insulating layer 140 is in contact with the oxide semiconductor layer 130 and the metal oxide layer 151. The metal oxide layer 151 overlaps the channel portion 131 of the oxide semiconductor layer 130. More specifically, as shown by the dash-dot line in FIG. 1, a position of an edge 151a of the metal oxide layer 151 and a position of an edge 131a of the channel portion 131 are coincident in the vertical direction in a cross-sectional view. In other words, in a cross-sectional view, the position of the edge 151a of the metal oxide layer 151 and the position of the boundary between the channel portion 131 and the conductive portion 132 are coincident in the vertical direction. The reason why the position of the edge 151a of the metal oxide layer 151 and the position of the edge 131a of the channel portion 131 coincide as described above will be described later.

The insulating layer 170 is provided on the insulating layer 140 and the metal oxide layer 151. In the present embodiment, a silicon oxide layer is used as the insulating layer 170. The insulating layer 170 is a dielectric layer that electrically insulates a layer on which the gate electrode 160 described later is formed or a layer on which the terminal electrode 181 is formed and a layer on which the oxide semiconductor layer 130 is formed. The thickness of the insulating layer 170 is 200 nm or more and 500 nm or less (preferably 350 nm or more and 450 nm or less). The thickness of the insulating layer 170 is greater than the thickness of the insulating layer 140.

The gate electrode 160 is provided on the insulating layer 170. The gate electrode 160 functions as a gate of the semiconductor device 10 (thin film transistor) similar to the gate electrode 105. Specifically, the gate electrode 160 has a function of applying the gate voltage to the channel portion 131 of the oxide semiconductor layer 130. The insulating layer 140, the metal oxide layer 151, and the insulating layer 170 sandwiched between the oxide semiconductor layer 130 and the gate electrode 160 function as the gate insulating layer. The gate insulating layer composed of the insulating layer 140, the metal oxide layer 151, and the insulating layer 170 may be referred to as an “upper gate insulating layer.” The insulating layer 190 is provided on the insulating layer 170 and the gate electrode 160. Although not shown, in the present embodiment, the insulating layer 190 has a two-layer structure. Specifically, a silicon oxide layer is used as an insulating layer on the lower layer side of the insulating layer 190 (a side closer to the substrate 100), and a silicon nitride layer is used as the insulating layer on the upper layer side of the insulating layer 190 (a side farther from the substrate 100). The insulating layers 140, 170, and 190 are provided with a contact hole 171 that reaches the conductive portion 132. In the present embodiment, the thickness of the insulating layer on the lower layer side (silicon oxide layer) is 100 nm, and the thickness of the insulating layer on the upper layer side (silicon nitride layer) is 300 nm, so that the thickness of the insulating layer 190 is 400 nm. The insulating layer 190 may have a single-layer structure or a structure of three or more layers.

The terminal electrode 181 is arranged on the insulating layer 190 and is electrically connected to the conductive portion 132 via the contact hole 171 provided in the insulating layers 140, 170, and 190. The terminal electrode 181 serves to supply carriers to the conductive portion 132 or to extract carriers from the conductive portion 132. That is, the terminal electrode 181 functions as a source electrode or a drain electrode of the semiconductor device 10 (thin film transistor) depending on the role of the conductive portion 132. Specifically, the terminal electrode 181 functions as a source electrode when the electrically connected conductive portion 132 functions as a source region, and the terminal electrode 181 functions as a drain electrode when the electrically connected conductive portion 132 functions as a drain region.

In the present embodiment, although a dual-gate transistor in which the gate electrode 105 is provided below the oxide semiconductor layer 130 and the gate electrode 160 is provided above the oxide semiconductor layer 130 is exemplified as the semiconductor device 10, the present embodiment is not limited to this configuration. For example, the semiconductor device 10 may be a bottom-gate transistor in which only the gate electrode 105 is provided or a voltage is applied only to the gate electrode 105, and may be a top-gate transistor in which only the gate electrode 160 is provided or a voltage is applied only to the gate electrode 160.

The gate electrode 105 may be referred to as a “first gate electrode.” The gate insulating layer 110 may be referred to as a “first gate insulating layer.” The insulating layer 140 may be referred to as a “second gate insulating layer.” The insulating layer 170 may be referred to as a “third gate insulating layer.” The gate electrode 160 may be referred to as a “second gate electrode.” Next, a planar structure of the semiconductor device 10 will be described with reference to FIG. 2. As shown in FIG. 2, the direction D1 is a direction in which the two terminal electrodes 181 are connected to each other (a direction in which the channel portion 131 and the conductive portion 132 are contiguous), and corresponds to a direction in which the carrier moves. In the oxide semiconductor layer 130, a length of the channel portion 131 in the direction D1 is a channel length (L), and a length of the channel portion 131 in a direction D2 is a channel width (W). The direction D2 is a direction intersecting the direction D1. In the present embodiment, the direction D2 indicates a direction orthogonal to the direction D1, but the direction D1 and the direction D2 may not be orthogonal depending on the layout of the oxide semiconductor layer 130.

In the present embodiment, in the direction D1, the width of the gate electrode 105 is greater than the length (channel length) of the channel portion 131. The reason for such a configuration is to effectively prevent intrusion of external light into the channel portion 131. However, the present invention is not limited to this example, and the length of the gate electrode 105 may be the same as the length of the channel portion 131.

As shown in FIG. 2, in a plan view, the metal oxide layer 151 is arranged to overlap the oxide semiconductor layer 130. Specifically, in a plan view, the metal oxide layer 151 is arranged to intersect the channel portion 131 of the oxide semiconductor layer 130. As described above, a width of the metal oxide layer 151 in the direction D2 is preferably larger than a width (W) of the oxide semiconductor layer 130 in the direction D2. Such a configuration is effective in effectively utilizing the above-described function of the metal oxide layer 151 (a function of suppressing hydrogen diffused from above from reaching the channel portion 131 of the oxide semiconductor layer 130).

Further, in a plan view, an outer edge of a portion of the metal oxide layer 151 overlapping the oxide semiconductor layer 130 coincides with an outer edge of the channel portion 131. In other words, the metal oxide layer 151 intersects the channel portion 131 and does not overlap the conductive portion 132. However, the expression “the metal oxide layer 151 intersects the channel portion 131 and does not overlap the conductive portion 132” includes the case where the metal oxide layer 151 overlaps a portion of the conductive portion 132 within an error range. As will be described later, the conductive portion 132 is formed by adding impurities to the oxide semiconductor layer 130 using a method such as ion implantation. Therefore, a portion of the conductive portion 132 may slightly overlap the metal oxide layer 151 due to the downward wrapping of impurities in the metal oxide layer 151.

In FIG. 2, although a configuration in which the terminal electrode 181 does not overlap the gate electrode 105 in a plan view is exemplified, the present embodiment is not limited to this configuration. For example, in a plan view, either or both of the two terminal electrodes 181 may overlap the gate electrode 105.

### 1-2. Material of Each Layer of Semiconductor Device

The substrate 100 supports each layer forming the semiconductor device 10. For example, a rigid substrate having light transmittance, such as a glass substrate, a quartz substrate, or a sapphire substrate, is used as the substrate 100. A rigid substrate having no light transmittance, such as a silicone substrate, may be used as the substrate. Further, a flexible substrate having light transmittance, such as a polyimide resin substrate, an acrylic resin substrate, a siloxane resin substrate, or a fluororesin substrate, may be used as the substrate. In order to improve the heat resistance of the substrate 100, impurities may be added to the resin substrate. A substrate on which a silicon oxide film or a silicon nitride film is deposited on the above-described rigid substrate or flexible substrate may be used as the substrate.

As described above, the gate electrode 105 has a larger area than the channel portion 131 of the oxide semiconductor layer 130. Therefore, a material capable of blocking external light incident on the channel portion 131 from below is used as the gate electrode 105. For example, aluminum (Al), copper (Cu), titanium (Ti), molybdenum (Mo), or tungsten (W), or an alloy or compound thereof is used as the gate electrode 105. The gate electrode 105 may have a single-layer structure or a stacked structure.

For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), aluminum nitride (AlNₓ), and the like are used as the gate insulating layer 110. In this case, silicon oxynitride (SiOₓN_{y}) and aluminum oxynitride (AlOₓN_{y}) are a silicon compound and aluminum compound containing a smaller proportion (x>y) of nitrogen (N) than oxygen (O), respectively. Silicon nitride oxide (SiNₓO_{y}) and aluminum nitride oxide (AlNₓO_{y}) are a silicon compound and aluminum compound containing a smaller proportion (x>y) of oxygen than nitrogen. In the present embodiment, the gate insulating layer 110 has a two-layer structure, a silicon nitride layer is used as the insulating layer on the lower layer side, and a silicon oxide layer is used as the insulating layer on the upper layer side.

The oxide semiconductor layer 130 may have an amorphous structure or a polycrystalline structure.

The insulating layers 140 and 170 contain an oxide having insulating properties. Specifically, silicon oxide (SiOₓ), silicon oxynitride (SiOₓN_{y}), aluminum oxide (AlOₓ), aluminum oxynitride (AlOₓN_{y}), and the like is used as the insulating layers 140 and 170. In the present embodiment, a silicon oxide layer having a thickness of 50 nm or more and 200 nm or less (preferably 50 nm or more and 150 nm or less, more preferably 100 nm or more and 150 nm or less) is used as the insulating layer 140. A silicon oxide layer having a thickness of 200 nm or more and 500 nm or less (preferably 350 nm or more and 450 nm or less) is used as the insulating layer 170.

The metal oxide layer 151 is composed of a metal oxide. In the present embodiment, an oxide containing aluminum as a main component (for example, aluminum oxide) is used as the metal oxide forming the metal oxide layer 151. Since aluminum oxide has a high barrier property against gas, the metal oxide layer 151 has a function of relaxing hydrogen diffusion into the channel portion 131 of the oxide semiconductor layer 130. An aluminum oxide layer having a thickness of 5 nm or more and 100 nm or less, 5 nm or more and 50 nm or less, 5 nm or more and 30 nm or less, or 7 nm or more and 15 nm or less is used as the metal oxide layer 151.

A material capable of blocking external light incident on the channel portion 131 from above is used as the gate electrode 160. For example, aluminum (Al), copper (Cu), titanium (Ti), molybdenum (Mo), or tungsten (W), or an alloy or compound thereof is used as the gate electrode 160. The gate electrode 160 may have a single-layer structure or a stacked structure.

For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), aluminum nitride (AlNₓ), and the like are used as the insulating layer 190. In the present embodiment, the insulating layer 190 has a two-layer structure, a silicon oxide layer is used as the insulating layer on the lower layer side, and a silicon nitride layer is used as the insulating layer on the upper layer side.

The terminal electrode 181 has conductivity. For example, copper (Cu), silver (Ag), aluminum (Al), titanium (Ti), chromium (Cr), cobalt (Co), nickel (Ni), molybdenum (Mo), hafnium (Hf), tantalum (Ta), tungsten (W), or bismuth (Bi), or an alloy or compound thereof is used as the terminal electrode 181. The terminal electrode 181 may have a single-layer structure or a stacked structure.

### 1-3. Method for Manufacturing Semiconductor Device

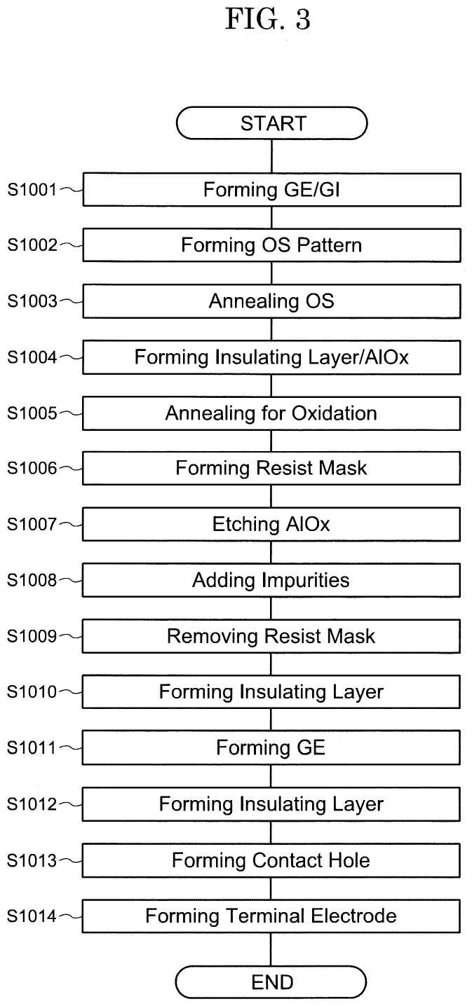

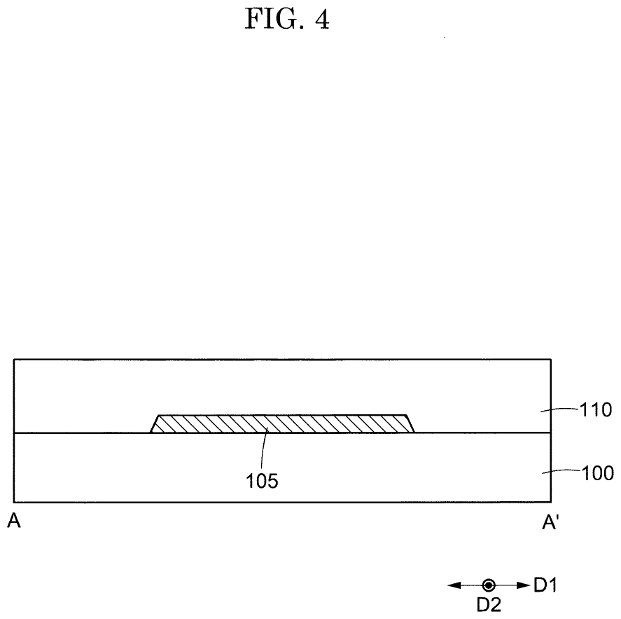

Next, a method for manufacturing the semiconductor device 10 according to an embodiment of the present invention will be described. FIG. 3 is a sequence diagram showing the method for manufacturing the semiconductor device 10 according to an embodiment of the present invention. FIG. 4 to FIG. 15 are schematic cross-sectional views showing the method for manufacturing the semiconductor device 10 according to an embodiment of the present invention.

As shown in FIG. 3 and FIG. 4, the gate electrode 105 is formed on the substrate 100, and the gate insulating layer 110 is formed on the gate electrode 105 (step S1001 in FIG. 4). For example, a stacked structure of a silicon nitride layer and a silicon oxide layer is formed as the gate insulating layer 110. The gate insulating layer 110 is formed by a CVD (Chemical Vapor Deposition) method. In the present specification, performing deposition on the substrate using a method such as a sputtering method or the CVD method, may be referred to as “forming a thin film,” and this expression is the same as the expression “depositing a thin film.” In the case where a silicon nitride layer is provided as a part of the gate insulating layer 110 on the side closer to the substrate 100, impurities that diffuse from the substrate 100 side toward the oxide semiconductor layer 130 can be blocked. In the case where a silicon oxide layer is provided as a part of the gate insulating layer 110 on a side in contact with the oxide semiconductor layer 130 to be formed later, characteristics of the interface between the gate insulating layer 110 and the oxide semiconductor layer 130 are improved.

By setting the deposition temperature of the silicon oxide layer to be relatively low, the amount of oxygen contained in the silicon oxide layer can be increased. As will be described later, by increasing the amount of oxygen contained in the gate insulating layer 110, the amount of hydrogen diffused into the oxide semiconductor layer 130 can be reduced. The deposition temperature of the gate insulating layer 110 is set to 250° C. or higher and 500° C. or lower (preferably 300° C. or higher and 450° C. or lower, and more preferably 325° C. or higher and 400° C. or lower).

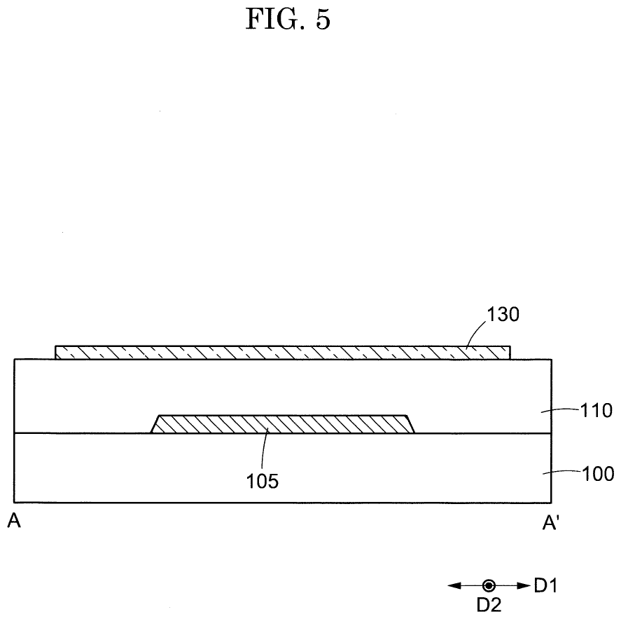

Next, as shown in FIG. 3 and FIG. 5, a patterned oxide semiconductor layer 130 is formed on the gate insulating layer 110 (step S1002 in FIG. 3). In the present embodiment, the process of forming the oxide semiconductor layer 130 is referred to as “Forming OS pattern.” That is, the oxide semiconductor layer 130 is formed by patterning the oxide semiconductor layer deposited on the gate insulating layer 110. In the explanation of the present embodiment, when the term “oxide semiconductor layer” is used without a reference sign, this refers to the oxide semiconductor layer in a deposited state (i.e., a non-processed state).

Wet etching may be used, or dry etching may be used for etching of the oxide semiconductor layers. For example, an acidic etchant (oxalic acid or hydrofluoric acid) is used as the wet etching.

In the present embodiment, the oxide semiconductor layer is formed by the sputtering method. For example, the thickness of the oxide semiconductor layer to be deposited is 10 nm or more and 100 nm or less, 10 nm or more and 70 nm or less, or 10 nm or more and 40 nm or less. In the present embodiment, the oxide semiconductor layer immediately after the deposition is amorphous. That is, the oxide semiconductor layer 130 (that is, the oxide semiconductor layer 130 immediately after patterning) before the heat treatment (OS annealing) described later is amorphous.

When thin film formation (film formation) is performed on the substrate by the sputtering method, ions generated in the plasma and atoms recoiled by a sputtering target collide with an object to be formed (specifically, a structure formed on the substrate 100), so that the temperature of the substrate increases in the thin film formation process.

In order to control the temperature (i.e., deposition temperature) of the substrate when forming the oxide semiconductor layer, for example, the thin film formation is performed while cooling the substrate. For example, the substrate is cooled from the opposite side of the surface to be formed so that the deposition temperature is 100° C. or lower, 70° C. or lower, 50° C. or lower, or 30° C. or lower. In particular, the deposition temperature of the oxide semiconductor layer of the present embodiment is preferably 50° C. or lower. In the present embodiment, a difference between the temperature at the time of forming the oxide semiconductor layer and the temperature at the time of performing the OS annealing on the oxide semiconductor layer 130 is preferably 350° C. or higher.

After the oxide semiconductor layer 130 is formed by patterning, a heat treatment (OS annealing) is performed on the oxide semiconductor layer 130 (step S1003 in FIG. 3). In the OS annealing process, the heat treatment is performed on the oxide semiconductor layer 130 in an atmosphere at a temperature of 250° C. or higher and 500° C. or lower (preferably 300° C. or higher and 500° C. or lower, and more preferably 350° C. or higher and 450° C. or lower). The heating atmosphere is not limited to an atmospheric atmosphere, and is preferably an oxidizing atmosphere (an atmosphere containing oxygen). The treatment time of the heat treatment after reaching the predetermined temperature is 15 minutes or more and 120 minutes or less, or 30 minutes or more and 60 minutes or less.

In the present embodiment, the substrate on which the oxide semiconductor layer 130 is formed is put into a heating furnace having a heating medium (for example, a support plate) that is maintained at a preset temperature (250° C. or higher and 500° C. or lower). The support plate as the heating medium has a function of supporting the substrate and a function of heating the substrate and a coating film (including the oxide semiconductor layer 130) formed on the substrate. When the substrate on which the oxide semiconductor layer 130 is formed is placed on the support plate, the oxide semiconductor layer 130 is rapidly heated. When the substrate is placed in the heating furnace, it is desirable to suppress the temperature drop of the support plate to within 15%, within 10%, or within 5% of the set temperature. That is, the temperature of the support plate is preferably controlled so that the oxide semiconductor layer 130 reaches the set temperature in as short a time as possible.

Next, as shown in FIG. 3 and FIG. 6, the insulating layer 140 and the metal oxide layer 150 are formed (step S1004 in FIG. 3). For example, a silicon oxide layer is formed as the insulating layer 140. The insulating layer 140 is formed by the CVD method. For example, the thickness of the insulating layer 140 is 50 nm or more and 200 nm or less, 50 nm or more and 150 nm or less, or 100 nm or more and 150 nm or less. In the present embodiment, the thickness of the insulating layer 140 is 100 nm.

The metal oxide layer 150 is formed by the sputtering method. By using the sputtering method for depositing the metal oxide layer 150, oxygen is implanted into the insulating layer 140 when the metal oxide layer 150 is formed. Therefore, a large amount of oxygen is contained in the insulating layer 140 after the metal oxide layer 150 is formed. For example, the thickness of the metal oxide layer 150 is 5 nm or more and 100nm or less, 5 nm or more and 50 nm or less, 5 nm or more and 30 nm or less, or 7 nm or more and 15 nm or less. In the present embodiment, aluminum oxide is used as the metal oxide layer 150. As described above, since the aluminum oxide has a high barrier property against gas, the oxygen implanted into the insulating layer 140 is suppressed from diffusing upward during the heat treatment to be described later.

In the case where the metal oxide layer 150 is formed by the sputtering method, a process gas used in sputtering remains in the film of the metal oxide layer 150. For example, in the case where Ar is used as the process gas for sputtering, Ar may remain in the film of the metal oxide layer 150. The remaining Ar is detected by the SIMS analysis or the like for the metal oxide layer 150. That is, in the case where Ar is used as the process gas for sputtering, Ar is detected by the SIMS analysis or the like for the metal oxide layer 151 obtained by patterning the metal oxide layer 150.

Next, with the metal oxide layer 150 formed on the insulating layer 140, a heat treatment (oxidation annealing) for supplying oxygen to the oxide semiconductor layer 130 is performed (step S1005 in FIG. 3). In a process between the formation of the oxide semiconductor layer 130 to the formation of the insulating layer 140 on the oxide semiconductor layer 130, oxygen vacancies may occur on an upper surface and a side surface of the oxide semiconductor layer 130. Oxygen released from the gate insulating layer 110 and the insulating layer 140 is supplied to the oxide semiconductor layer 130 by the oxidation annealing process, and the oxygen vacancies are repaired. The oxidation annealing process is performed at a temperature of 250° C. or higher and 500° C. or lower (preferably 300° C. or higher and 500° C. or lower, and more preferably 350° C. or higher and 450° C. or lower).

Oxygen released from the gate insulating layer 110 and the insulating layer 140 is supplied to the oxide semiconductor layer 130 by the oxidation annealing process. In the case where a silicon nitride layer is used as a part of the gate insulating layer 110, hydrogen may be released from the gate insulating layer 110 by the oxidation annealing process described above, but most of the released hydrogen is captured by oxygen contained in the silicon oxide layer arranged above the silicon nitride layer before reaching the oxide semiconductor layer 130.

As described above, oxygen is supplied to the oxide semiconductor layer 130 by the oxidation annealing process. During the oxidation annealing process, the upward diffusion of the oxygen implanted into the insulating layer 140 is blocked by the metal oxide layer 150, so that the diffused oxygen is suppressed from being released into the atmosphere. Therefore, oxygen is efficiently supplied to the oxide semiconductor layer 130 during the oxidation annealing process.

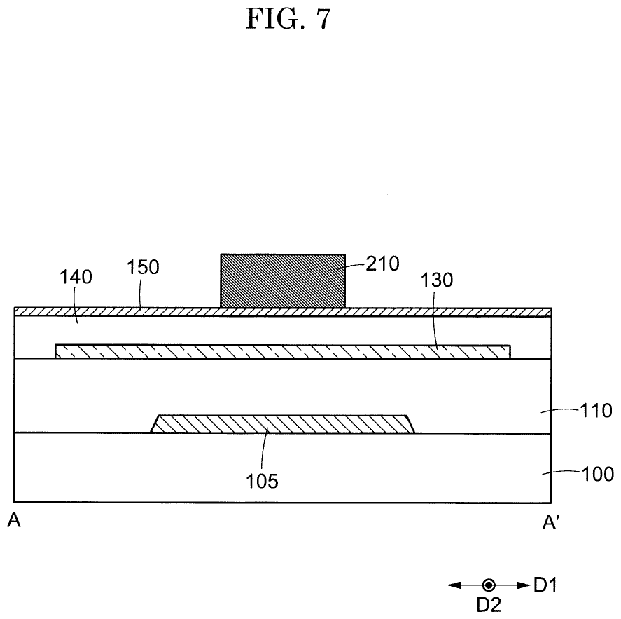

Next, as shown in FIG. 3 and FIG. 7, a resist mask 210 is formed on the metal oxide layer 150 (step S1006 in FIG. 3). The resist mask 210 is arranged so as to overlap the oxide semiconductor layer 130. As will be described later, a portion of the oxide semiconductor layer 130 that overlaps the resist mask 210 corresponds to a portion where the channel portion 131 is formed. As shown in FIG. 2, the resist mask 210 is arranged to intersect the oxide semiconductor layer 130 in the direction D2.

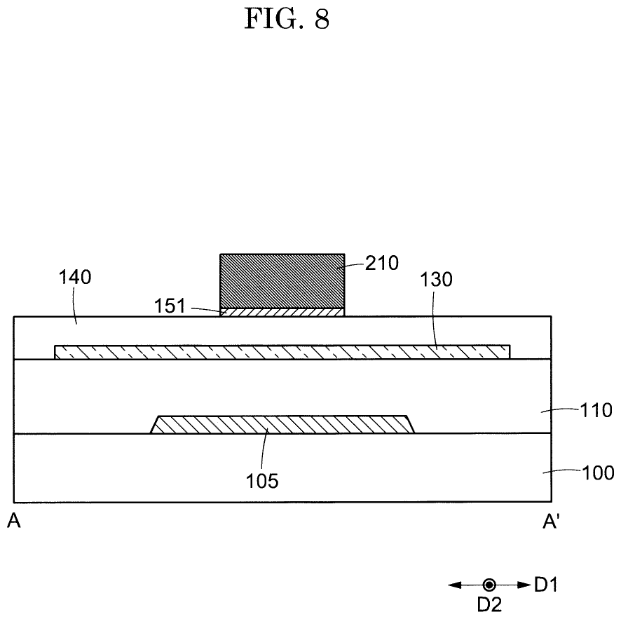

Next, as shown in FIG. 3 and FIG. 8, the metal oxide layer 150 is etched using the resist mask 210 as a mask to form the metal oxide layer 151 (step S1007 in FIG. 3). The etching of the metal oxide layer 150 may be wet etching or dry etching. For example, dilute hydrofluoric acid (DHF) is used as the wet etching.

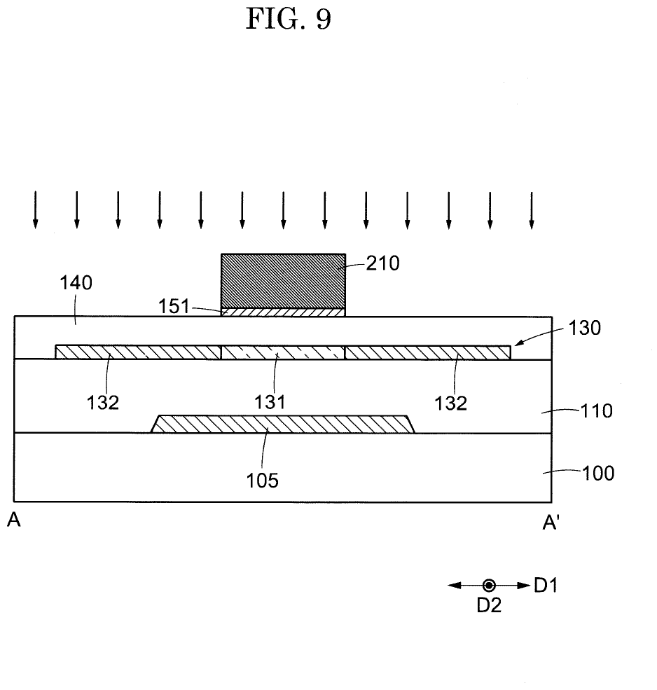

Next, as shown in FIG. 3 and FIG. 9, ions are implanted from above the resist mask 210, and an impurity is implanted into the oxide semiconductor layer 130 (step S1008 in FIG. 3). Phosphorus, boron, argon, or the like is used as the impurity. The purpose of adding the impurity is to increase conductivity by forming oxygen vacancies in a partial region of the oxide semiconductor layer 130. Therefore, an element having a large atomic radius is preferably used as the impurity. In the present embodiment, although an example in which the impurity is added by ion implantation is shown, the impurity may be added by ion doping. In the present embodiment, boron is added by ion implantation. Conditions of the ion implantation process of the present embodiment are an acceleration voltage of 30 keV and a dose amount of 1×10¹⁵/cm², but are not limited to this example.

As shown in FIG. 9, when an impurity ion is implanted into the oxide semiconductor layer 130, the conductive portion 132 is formed in the oxide semiconductor layer 130. In this case, a region where the impurity is not implanted and the original state is maintained functions as the channel portion 131. That is, in a cross-sectional view, a position of end portions of the resist mask 210 and the metal oxide layer 151 and a position of end portions of the channel portion 131 are coincident in the vertical direction.

Impurities are added to the conductive portion 132 via the insulating layer 140 by the ion implantation process. As described above, the conductive portion 132 functions as the source region or drain region of the semiconductor device 10.

In the present embodiment, the upper gate insulating layer between the oxide semiconductor layer 130 and the gate electrode 160 is composed of the insulating layer 140, the metal oxide layer 151, and the insulating layer 170. That is, since the withstand voltage characteristics of the gate insulating layer required for the semiconductor device 10 do not need to be achieved only by the insulating layer 140, the thickness of the insulating layer 140 can be set to 50 nm or more and 200 nm or less (preferably, 50 nm or more and 150 nm or less, more preferably, 100 nm or more and 150 nm or less). Since the metal oxide layer 150 is removed from a region other than directly under the resist mask 210, the insulating layer 140 is exposed. In other words, impurities can be added to the oxide semiconductor layer 130 without passing through the metal oxide layer having a high barrier property against gas. As described above, in the present embodiment, the thickness of the insulating layer 140 can be reduced, and since it is not necessary for the impurity to pass through the dense metal oxide layer, the dose amount of impurities can be increased even at a relatively low acceleration voltage. That is, since a sufficient amount of impurities can be added to the oxide semiconductor layer 130 without imposing an excessive burden on the manufacturing device used for the impurity addition, a resistance value of the conductive portion 132 can be sufficiently reduced.

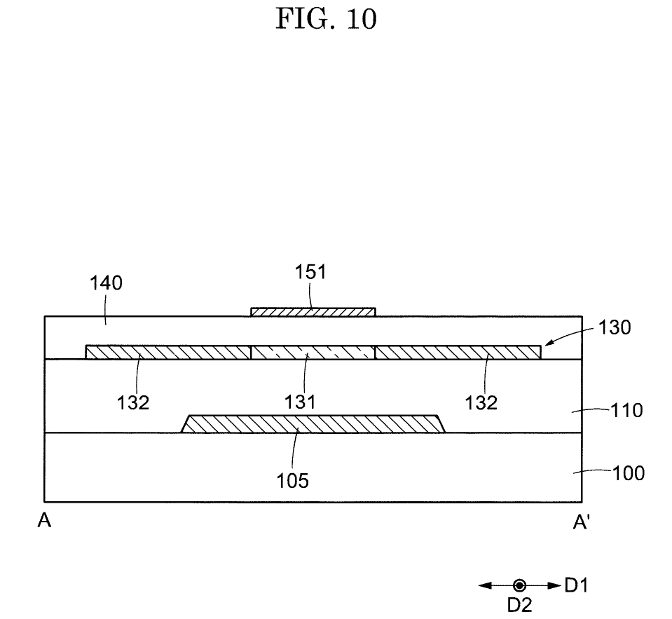

Next, as shown in FIG. 3 and FIG. 10, the resist mask 210 is removed (step S1009 in FIG. 3). By removing the resist mask 210, the metal oxide layer 151 composed of the metal oxide remains on the insulating layer 140.

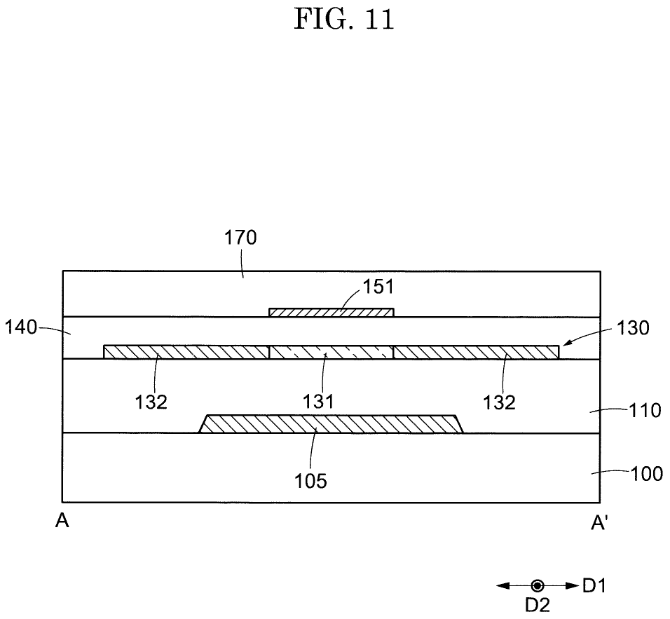

Next, as shown in FIG. 3 and FIG. 11, the insulating layer 170 is formed on the insulating layer 140 and the metal oxide layer 151 (step S1010 in FIG. 3). As described above, any material may be selected from silicon oxide (SiOₓ), silicon nitride (SiNₓ), silicon oxynitride (SiOₓN_{y}), silicon nitride oxide (SiOₓN_{y}), or resin as the material forming the insulating layer 170.

In the present embodiment, a silicon oxide layer is formed as the insulating layer 170 by the CVD method. For example, the thickness of the insulating layer 170 is 200 nm or more and 500 nm or less (preferably 350 nm or more and 450 nm or less). In the present embodiment, a silicon oxide layer of 400 nm is formed as the insulating layer 170.

The deposition temperature of the insulating layer 170 is preferably set to 250° C. or higher and 500° C. or lower (preferably 300° C. or higher and 450° C. or lower, and more preferably 325° C. or higher and 400° C. or lower).

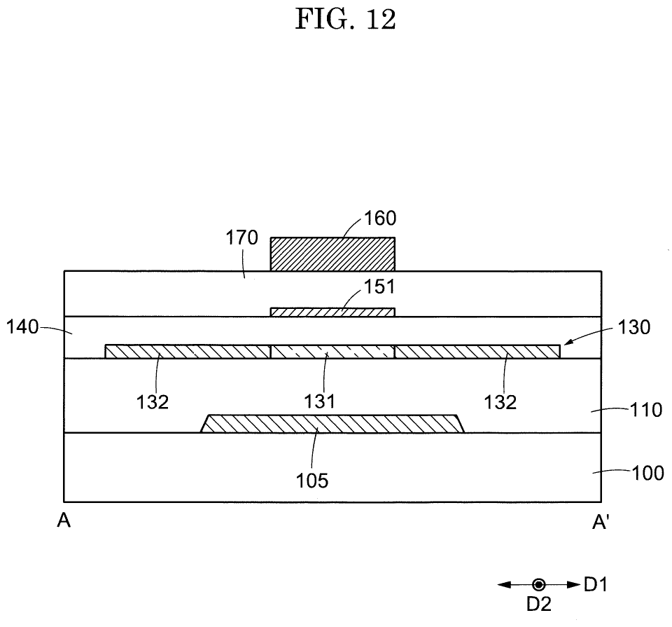

Next, as shown in FIG. 3 and FIG. 12, the gate electrode 160 is formed on the insulating layer 170 (step S1011 in FIG. 3). As described above, any material may be selected from aluminum (Al), copper (Cu), titanium (Ti), molybdenum (Mo), or tungsten (W), or an alloy or compound thereof as the gate electrode 160. The gate electrode 160 may have a single-layer structure or a stacked structure. In the present embodiment, a stacked structure composed of titanium and a molybdenum-tungsten alloy is formed using the sputtering method as the gate electrode 160.

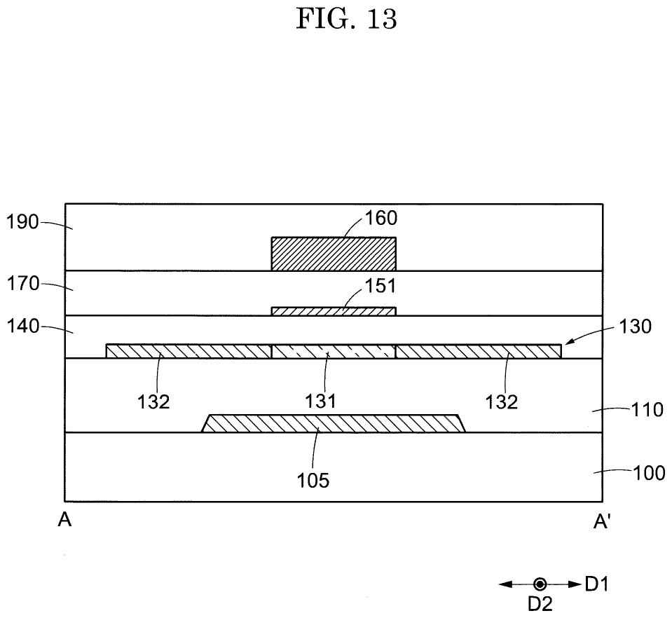

Next, as shown in FIG. 3 and FIG. 13, the insulating layer 190 is formed on the insulating layer 170 and the gate electrode 160 (step S1012 in FIG. 3). As described above, any material may be selected from silicon oxide (SiOₓ), silicon nitride (SiNₓ), silicon oxynitride (SiOₓN_{y}), silicon nitride oxide (SiOₓN_{y}), or resin as the material forming the insulating layer 190.

In the present embodiment, a stacked structure composed of a silicon oxide layer and a silicon nitride layer is formed as the insulating layer 190 using the CVD method. In the present embodiment, the thickness of the silicon oxide layer formed on the lower layer side of the insulating layer 190 is 100 nm, and the thickness of the silicon nitride layer formed on the upper layer side of the insulating layer 190 is 300 nm. That is, the thickness of the insulating layer 190 of the present embodiment is 400 nm. However, the thickness of the insulating layer 190 is not limited to this example, and may be thicker or thinner than the thickness described above.

The deposition temperature of the insulating layer 190 is set to 250° C. or higher and 500° C. or lower (preferably 300° C. or higher and 450° C. or lower, and more preferably 325° C. or higher and 400° C. or lower).

The insulating layer 190 functions as a passivation layer for preventing gas and moisture from entering from the outside. As described above, the insulating layer 190 also serves to insulate the terminal electrode 181 from the conductive portion 132 of the oxide semiconductor layer 130. Further, in the present embodiment, since a silicon nitride layer is used as a part of the insulating layer 190, the insulating layer 190 promotes the reduction of the resistance of the conductive portion 132.

In the case where the silicon nitride layer is formed by the CVD method, since ammonia is used as the source gas, the silicon nitride layer contains a large amount of hydrogen. Therefore, since the insulating layer 190 is heated when the insulating layer 190 is formed and after the insulating layer 190 is formed, hydrogen diffuses from the silicon nitride layer. The diffused hydrogen reaches the conductive portion 132 via the silicon oxide layer on the lower side of the insulating layer 190 and the insulating layers 140 and 170. In this case, hydrogen is trapped in the oxygen vacancies inside the conductive portion 132 formed by the ion implantation process described above, and a donor level is formed. As a result, the resistance of the conductive portion 132 is reduced. In this case, the metal oxide layer 151 functions as a barrier layer that suppresses movement of hydrogen that diffuses from the insulating layer 190 toward the channel portion 131 of the oxide semiconductor layer 130.

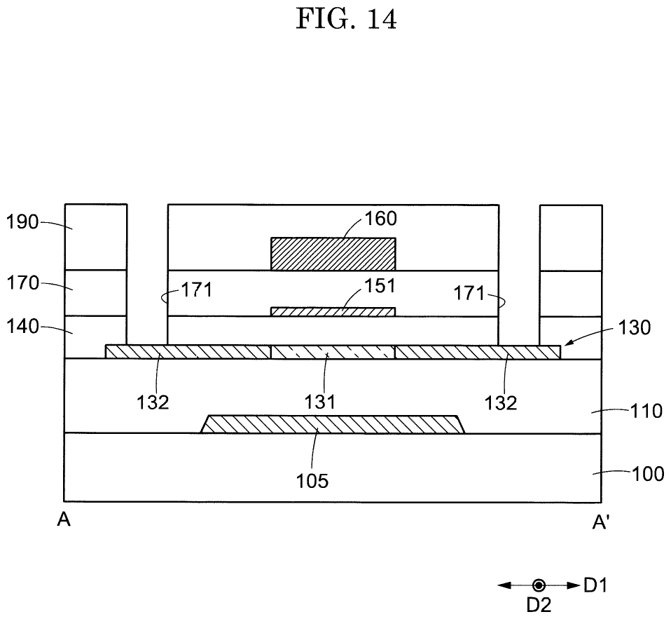

Next, as shown in FIG. 3 and FIG. 14, the contact hole 171 is formed in the insulating layer 140, 170, and 190 (step S1013 in FIG. 3). The contact hole 171 exposes a portion of the conductive portion 132. In this case, in the present embodiment, since the metal oxide layer 150 located directly above the conductive portion 132 is removed, there is an advantage that the contact hole 171 is easily formed.

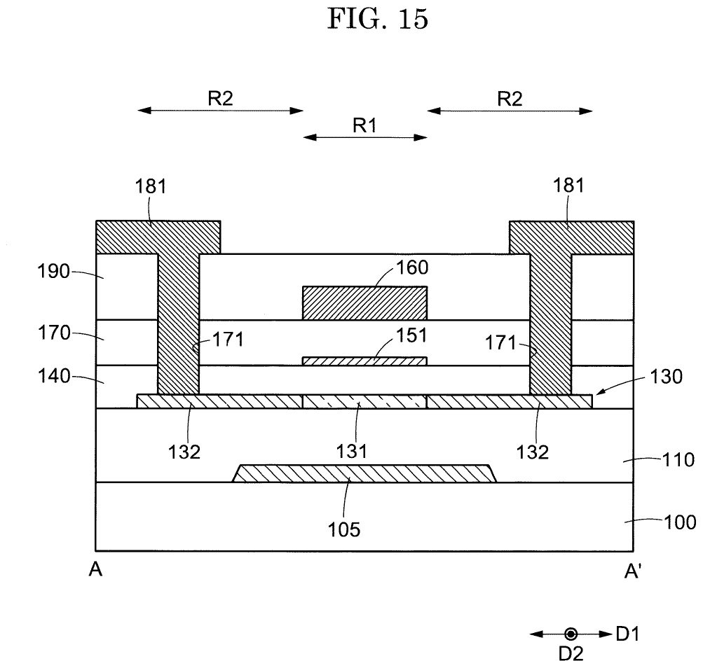

Finally, as shown in FIG. 3 and FIG. 15, the terminal electrode 181 is formed on the conductive portion 132 exposed by the contact hole 171 (step S1014 in FIG. 3). Through the processes described above, the semiconductor device 10 shown in FIG. 1 is completed.

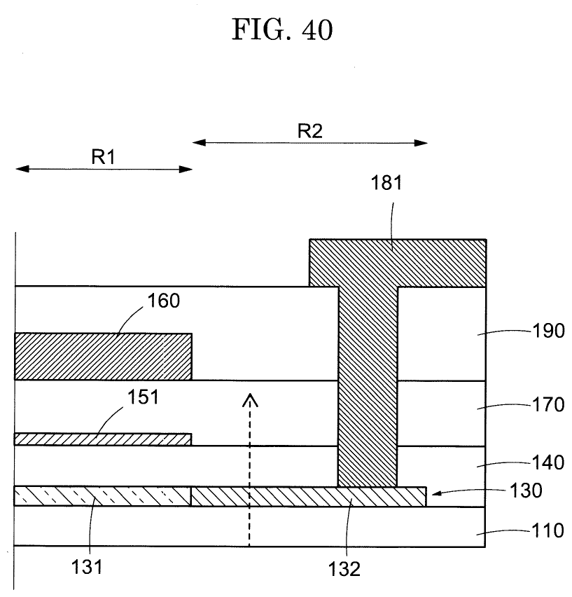

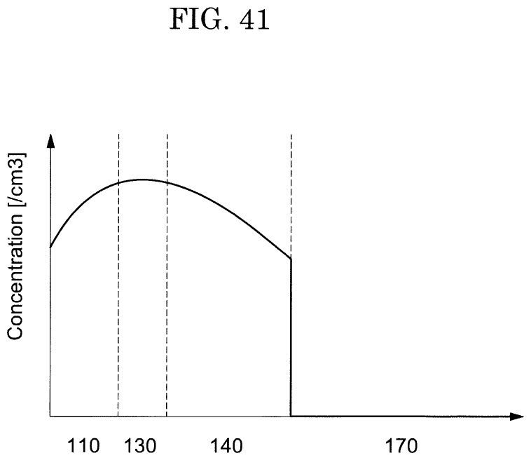

As described above, since the impurity is added to the oxide semiconductor layer 130 via the insulating layer 140 and the insulating layer 170 is formed on the insulating layer 140 after the impurity is added, the insulating layer 140 contains the impurity, but the insulating layer 170 does not contain the impurity in the second region R2. In this case, the profile of the impurities contained in the insulating layer 140 and the insulating layer 170 will be described with reference to FIG. 40 and FIG. 41. FIG. 40 is a diagram showing a region where the impurity concentration was evaluated in the semiconductor device according to the embodiment of the present invention. FIG. 40 is an enlarged view of a portion of FIG. 1. FIG. 41 is a diagram showing evaluation results of the impurity concentration of the semiconductor device according to an embodiment of the present invention. When the SIMS analysis is performed in the direction of the dashed arrow in FIG. 40, a SIMS profile as shown in FIG. 41 is obtained. The horizontal axis of FIG. 41 indicates the layer in which the impurity concentration has been calculated by the SIMS analysis. The vertical axis of FIG. 41 indicates the concentration of impurities calculated by the SIMS analysis. The impurity shown in FIG. 41 is the impurity added to the oxide semiconductor layer 130 for reducing the resistance of the oxide semiconductor layer 130.

As shown in FIG. 41, in the vicinity of the boundary between the insulating layer 140 and the insulating layer 170 in the second region R2, the concentration of impurities contained in the insulating layer 140 is 100 times or more the concentration of impurities contained in the insulating layer 170. That is, the average concentration of impurities of the insulating layer 140 in the thickness direction is 100 times or more the average concentration of impurities of the insulating layer 170 in the thickness direction.

In the semiconductor device 10 of the present embodiment, an insulating layer having a thickness of 200 nm or more (preferably 300 nm or more) can be used as the gate insulating layer 110, and an insulating layer having a thickness of 250 nm or more (preferably 350 nm or more) can be used as the upper gate insulating layer (the insulating layer 140, the metal oxide layer 151, and the insulating layer 170), so that the withstand voltage characteristics of the gate insulating layer above and below the oxide semiconductor layer 130 can be sufficiently ensured. When the conductive portion 132 is formed in the oxide semiconductor layer 130, since the resistance of the oxide semiconductor layer 130 is reduced by adding an impurity via the insulating layer 140, damage to the oxide semiconductor layer 130 (in particular, damage to the channel portion 131) can be suppressed. In this case, since the thickness of the insulating layer 140 is 200 nm or less (preferably 150 nm or less), the resistivity of the conductive portion 132 can be sufficiently reduced by adding a sufficient amount of impurities while suppressing the load on the device used for the impurity addition. As described above, according to the present embodiment, reliability of the semiconductor device 10 including the oxide semiconductor can be improved.

### 1-4. Mobility of Semiconductor Device 10

“Field-effect mobility” in the present specification is a field-effect mobility in a saturated region of the semiconductor device 10, and means a maximum value of the field-effect mobility in a region in which a potential difference (Vd) between the source and the drain is greater than a value (Vg-Vth) obtained by subtracting a threshold voltage (Vth) of the semiconductor device 10 from a voltage (Vg) supplied to the gate.

### 1-5. First Modification of First Embodiment

In the semiconductor device 10 described above, although an example in which the metal oxide layer 150 is etched to form the patterned metal oxide layer 151 has been described, the metal oxide layer 150 may remain without being patterned.

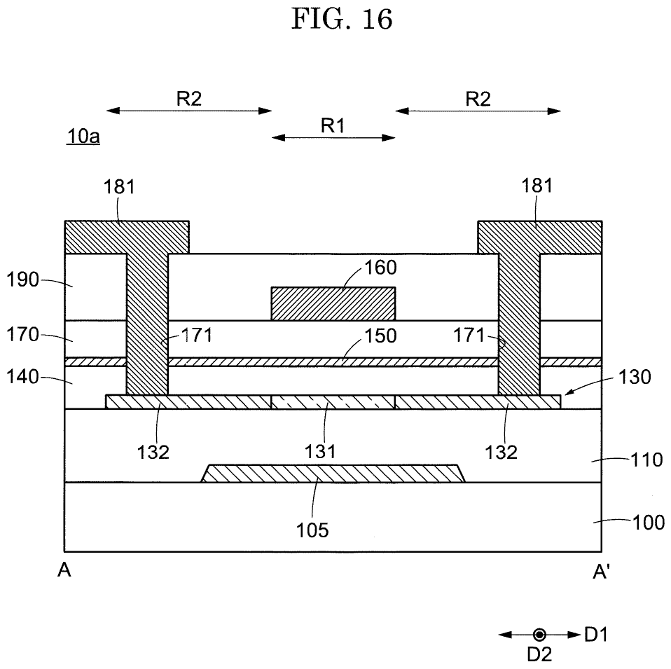

FIG. 16 is a schematic cross-sectional view showing a configuration of a semiconductor device 10a according to a modification of an embodiment of the present invention. In the semiconductor device 10a of the present modification, the metal oxide layer 150 is not patterned and remains on the insulating layer 140. That is, the metal oxide layer 150 overlaps the conductive portion 132 in addition to the channel portion 131 of the oxide semiconductor layer 130 in a plan view. In other words, the metal oxide layer 150 is provided in both the first region R1 and the second region R2.

In the semiconductor device 10a of the present modification, similar to the metal oxide layer 151 shown in FIG. 1, the metal oxide layer 150 functions as a barrier layer that suppresses hydrogen diffused from above from reaching the oxide semiconductor layer 130.

### 1-6. Second Modification of First Embodiment

In the semiconductor device 10 described above, although an example in which the metal oxide layer 150 is etched to form the patterned metal oxide layer 151 has been shown, the metal oxide layer 150 may be removed by etching without being patterned.

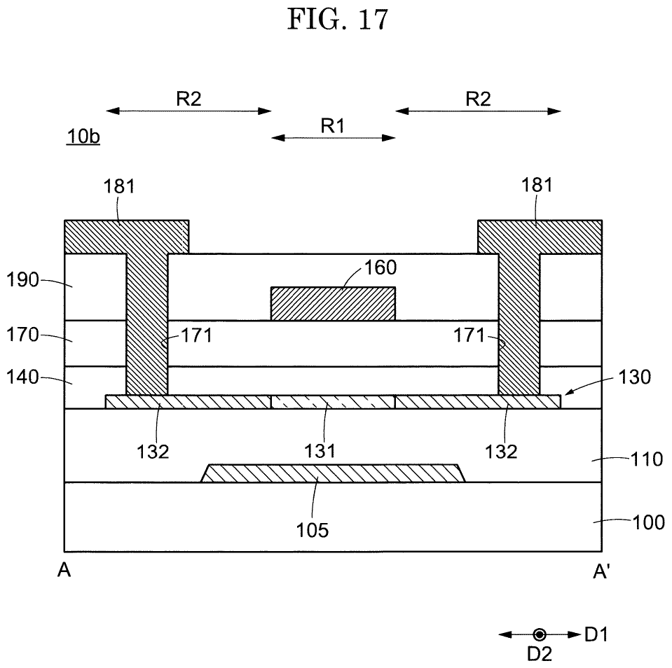

FIG. 17 is a schematic cross-sectional view showing a configuration of a semiconductor device 10b according to a modification of an embodiment of the present invention. The semiconductor device 10b is provided with a step of completely removing the metal oxide layer 150 formed on the insulating layer 140 by etching after the oxidation annealing process shown in step S1005 in FIG. 3. That is, in the present modification, neither the metal oxide layer 151 shown in FIG. 1 nor the metal oxide layer 150 shown in FIG. 16 is present on the insulating layer 140.

According to the present modification, in the process of adding impurities to the oxide semiconductor layer 130 shown in S1008 in FIG. 3, the dose amount of impurities to be added can be sufficiently increased even if the acceleration voltage is set low. According to the present modification, the contact hole 171 can be easily formed in the insulating layers 140, 170, and 190 shown in S1013 in FIG. 3.

### 2. Second Embodiment

In the present embodiment, a semiconductor device 20 in which the configuration of the oxide semiconductor layer 130 is different from that of the semiconductor device 10 of the first embodiment will be described. In the description of the present embodiment, the same reference signs are used to denote the same elements as those of the first embodiment, and the description thereof may be omitted.

### 2-1. Configuration of Semiconductor Device

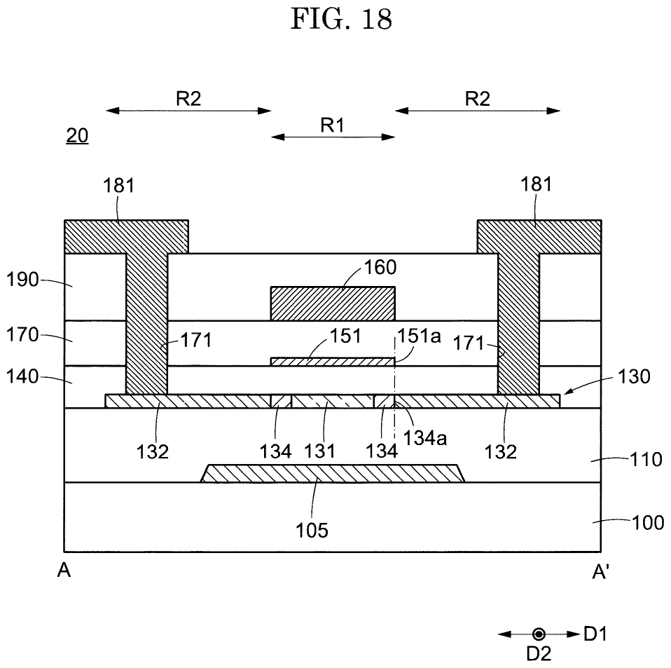

FIG. 18 is a schematic cross-sectional view showing a configuration of the semiconductor device 20 according to an embodiment of the present invention. The difference from the semiconductor device 10 shown in FIG. 1 is that an LDD portion 134 is provided in the oxide semiconductor layer 130. “LDD” is an abbreviation for “Light Doped Drain.” That is, the LDD portion 134 indicates a portion having a lower resistance value than the channel portion 131 and a higher resistance value than the conductive portion 132. As shown in FIG. 18, the LDD portion 134 is arranged between the channel portion 131 and the conductive portion 132. In other words, the oxide semiconductor layer 130 of the present embodiment has a structure in which the channel portion 131, the LDD portion 134, and the conductive portion 132 are contiguous in the direction D1.

The metal oxide layer 151 composed of a metal oxide overlaps the channel portion 131 and the LDD portion 134. In the present embodiment, in a cross-sectional view, the position of the edge 151a of the metal oxide layer 151 and a position of an edge 134a of the LDD portion 134 are coincident in the vertical direction. In other words, in a cross-sectional view, the position of the edge 151a of the metal oxide layer 151 and the position of the boundary between the LDD portion 134 and the conductive portion 132 are coincident in the vertical direction. As described above, in the present embodiment, since the width of the metal oxide layer 151 is wider than the width of the channel portion 131 in the direction D1, it is effective in effectively utilizing the function of the metal oxide layer 151 described above (the function of suppressing the hydrogen diffused from above from reaching the channel portion 131 of the oxide semiconductor layer 130). However, the present invention is not limited to this configuration, and the metal oxide layer 151 may not overlap the LDD portion 134.

Other advantages of the semiconductor device 20 of the present embodiment are similar to those of the semiconductor device 10 of the first embodiment.

### 2-2. Method for Manufacturing Semiconductor Device

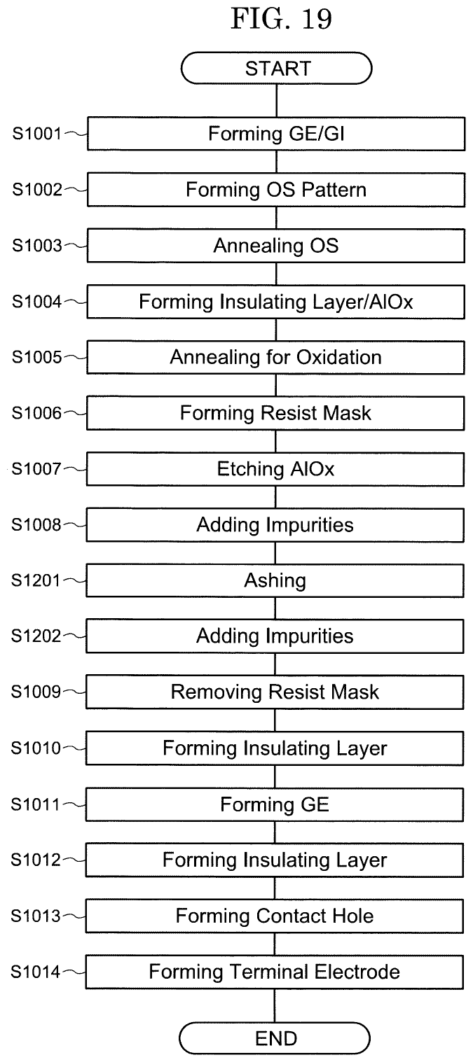

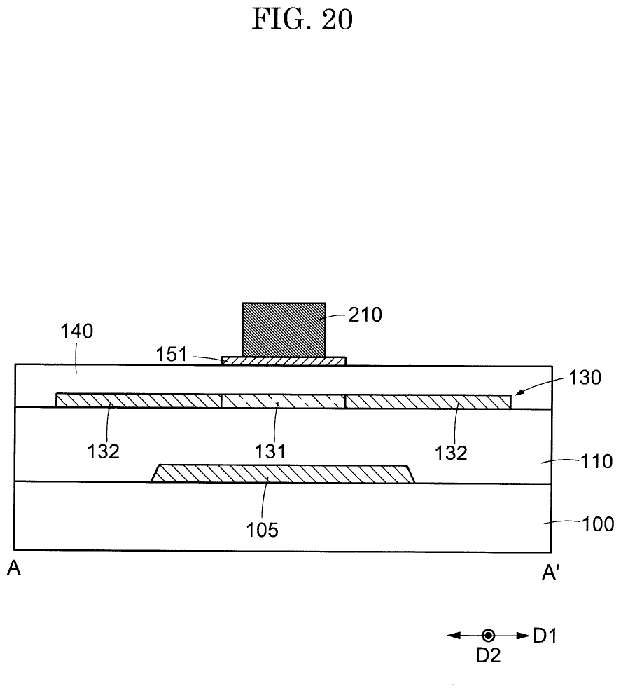

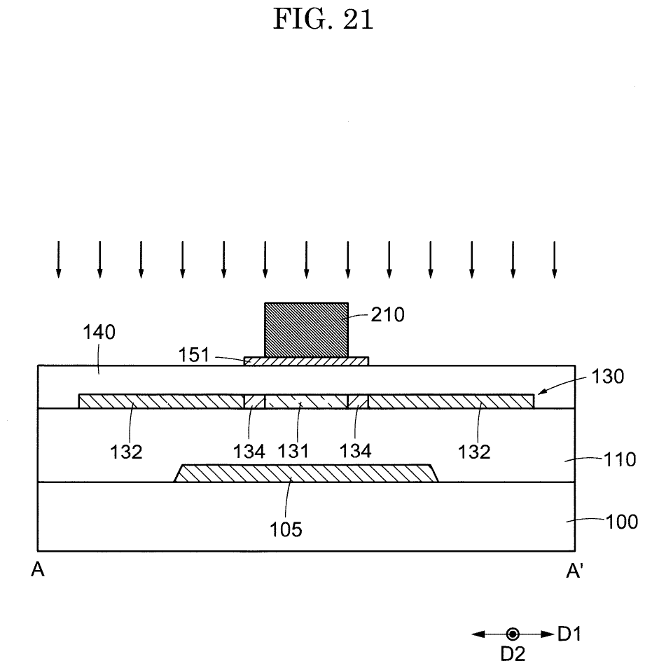

Next, a method for manufacturing the semiconductor device 20 according to an embodiment of the present invention will be described. FIG. 19 is a sequence diagram showing the method for manufacturing the semiconductor device 20 according to an embodiment of the present invention. FIG. 20 to FIG. 21 are schematic cross-sectional views showing the method for manufacturing the semiconductor device 20 according to an embodiment of the present invention.

In the method for manufacturing the semiconductor device 20 of the present embodiment, step S1001 to step S1008 shown in FIG. 19 are the same as step S1001 to step S1008 shown in FIG. 3 of the first embodiment. The manufacturing method of the present embodiment is different from the manufacturing method of the first embodiment in that step S1201 and step S1202 shown in FIG. 19 are added between step S1008 and step S1009 shown in FIG. 3.

First, similar to the first embodiment, the conductive portion 132 is formed by adding impurities to the oxide semiconductor layer 130 by step S1001 to step S1008 in FIG. 3. Next, as shown in FIG. 20 and FIG. 21, an ashing treatment is performed on the resist mask 210 in an oxidizing atmosphere (step S1201 in FIG. 19). By performing the ashing treatment, a width of the resist mask 210 in the direction D1 is narrowed, and a part of the upper surface of the metal oxide layer 151 is exposed.

Next, as shown in FIG. 19 and FIG. 21, ions are implanted from above the resist mask 210, and the second impurity is added to the oxide semiconductor layer 130 (step S1202 in FIG. 19). The impurities to be added are the same as those used in the impurity addition in step S1008 in FIG. 19 (phosphorus, boron, argon, or the like).

Conditions of the ion implantation process may be the same as or different from step S1008 in FIG. 19. In the present embodiment, similar to step S1008, the acceleration voltage is 30 keV and the dose amount is 1×10¹³/cm². As shown in FIG. 21, in the present embodiment, the LDD portion 134 is formed at end portions (portions not overlapping the resist mask 210) of the channel portion 131 in the direction D1 by the second impurity addition. In this case, since the impurities are added to the LDD portion 134 via the metal oxide layer 151 and the insulating layer 140, the amount of impurities to be added is smaller than that of the conductive portion 132 even if the impurities are added under the same conditions as in step S1008. That is, the resistance value of the LDD portion 134 is higher than the resistance value of the conductive portion 132. However, the dose amount in step S1202 may be smaller than the dose amount in step S1008.

After the LDD portion 134 is formed through the processes described above, the semiconductor device 20 shown in FIG. 18 is completed through step S1009 to step S1014 shown in FIG. 19. Step S1009 to step S1014 shown in FIG. 19 are the same as step S1009 to step S1014 shown in FIG. 3 of the first embodiment.

### 2-3. Modification of Second Embodiment

In the semiconductor device 20 described above, although an example in which the process shown in FIG. 21 is performed without processing the metal oxide layer 151 after the ashing treatment is performed on the resist mask 210 has been described, a portion of the metal oxide layer 151 may be removed using the resist mask 210 as a mask. That is, in FIG. 20, etching may be performed on the end portion of the metal oxide layer 151 using the resist mask 210 as a mask, and a portion exposed from the resist mask 210 may be removed.

In the case of the present modification, in the process shown in FIG. 21, an impurity is added to the LDD portion 134 via the insulating layer 140. That is, since the metal oxide layer 151 does not overlap the LDD portion 134, the LDD portion 134 is not formed when the impurity addition is performed under the same conditions as in S1008 in FIG. 19. Therefore, in the present modification, at the time of the second impurity addition (step S1202 in FIG. 19), the amount of impurities to be added to the LDD portion 134 is adjusted by reducing the acceleration voltage and the dose amount as compared with the first impurity addition process (step S1008 in FIG. 19).

### 3. Third Embodiment

Although an example in which the oxide semiconductor layer 130 is provided to be in contact with the gate insulating layer 110 has been described in the first embodiment, a metal oxide layer is provided between the gate insulating layer 110 and the oxide semiconductor layer 130 in the present embodiment. In the description of the present embodiment, the same reference signs are used to denote the same elements as those of the first embodiment, and the description thereof may be omitted.

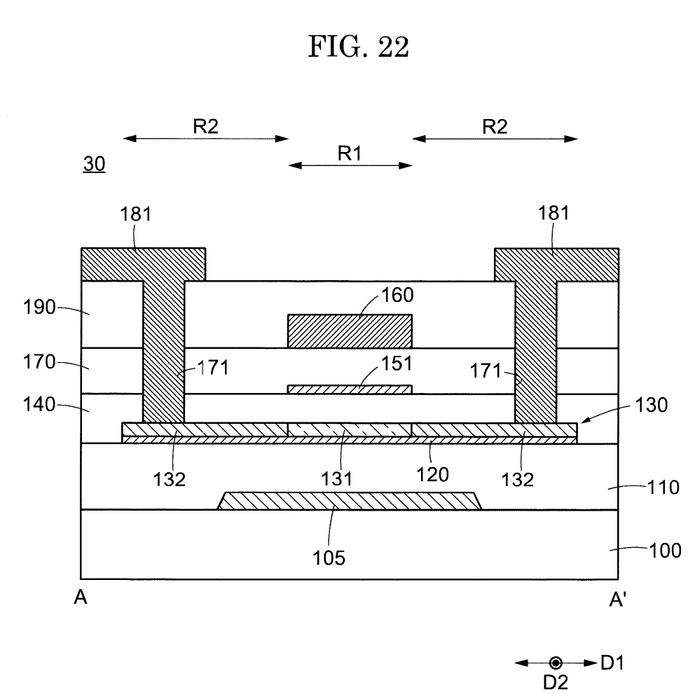

FIG. 22 is a schematic cross-sectional view showing a configuration of a semiconductor device 30 according to an embodiment of the present invention. Although the basic structure is the same as that of the semiconductor device 10 shown in FIG. 1, in the semiconductor device 30 of the present embodiment, a metal oxide layer 120 is arranged between the gate insulating layer 110 and the oxide semiconductor layer 130. In the present embodiment, a metal oxide containing aluminum as a main component (specifically, an aluminum oxide layer) is used as the metal oxide layer 120. For example, the metal oxide layer 120 is formed by the sputtering method.

As shown in FIG. 22, in the present embodiment, the metal oxide layer 120 has the same pattern shape as that of the oxide semiconductor layer 130. In the present embodiment, step S1001 of FIG. 3 is performed, and then the metal oxide layer 120 and the oxide semiconductor layer 130 are contiguously deposited. After that, the processes of step S1002 and step S1003 in FIG. 3 are performed to form the oxide semiconductor layer 130. Further, by etching the oxide semiconductor layer 130 and the metal oxide layer 120, the metal oxide layer 120 having the same pattern shape as that of the oxide semiconductor layer 130 is formed.

For example, the thickness of the metal oxide layer 120 is 1 nm or more and 10 nm or less, 1 nm or more and 4 nm or less, or 1 nm or more and 3 nm or less. In the present embodiment, the thickness of the metal oxide layer 120 is 3 nm. In the present embodiment, the aluminum oxide layer used as the metal oxide layer 120 has a high barrier property against gas even when the thickness is 1 nm or more and 10 nm or less. Therefore, the metal oxide layer 120 of the present embodiment blocks hydrogen and oxygen released from the gate insulating layer 110, and suppresses the hydrogen and oxygen released from below from reaching the oxide semiconductor layer 130. By blocking the hydrogen released from the gate insulating layer 110 by the metal oxide layer 120, the reduction reaction of the oxide semiconductor layer 130 is suppressed.

After the oxide semiconductor layer 130 is formed, more oxygen vacancies are formed on the upper layer side of the oxide semiconductor layer 130 than on the lower layer side through various manufacturing processes (such as a patterning process). That is, the oxygen vacancies in the oxide semiconductor layer 130 are present in a non-uniform distribution in the thickness direction. In this case, if a sufficient amount of oxygen is supplied to repair the oxygen vacancies formed on the upper layer side of the oxide semiconductor layer 130, excessive oxygen is supplied to the lower layer side of the oxide semiconductor layer 130. As a result, a defect level different from the oxygen vacancies may be formed due to the excessively supplied oxygen, which may lead to a phenomenon such as a characteristic variation in a reliability test or a decrease in the field-effect mobility. Therefore, by blocking the oxygen released from the gate insulating layer 110 by the metal oxide layer 120, excessive oxygen supply to the lower layer of the oxide semiconductor layer 130 is suppressed.

As described above, in the present embodiment, in the case where the oxidation annealing process shown in step S1005 of FIG. 3 is performed, oxygen is supplied to the upper surface and the side surface of the oxide semiconductor layer 130 having a relatively large amount of oxygen vacancies while suppressing the supply of oxygen to the lower surface of the oxide semiconductor layer 130 having a small amount of oxygen vacancies. Therefore, oxygen is efficiently supplied to the oxide semiconductor layer 130 during the oxidation annealing process, and the reliability of the semiconductor device 30 is improved.

In the present embodiment, although an example has been shown in which the metal oxide layer 120 is applied to the semiconductor device 10 shown in FIG. 1 of the first embodiment, the metal oxide layer 120 may be applied to other semiconductor devices.

### 4. Fourth Embodiment

In the present embodiment, a semiconductor device 40 having a layer structure different from that of the semiconductor device 10 of the first embodiment will be described. In the description of the present embodiment, the same reference signs are used to denote the same elements as those of the first embodiment, and the description thereof may be omitted.

### 4-1. Configuration of Semiconductor Device

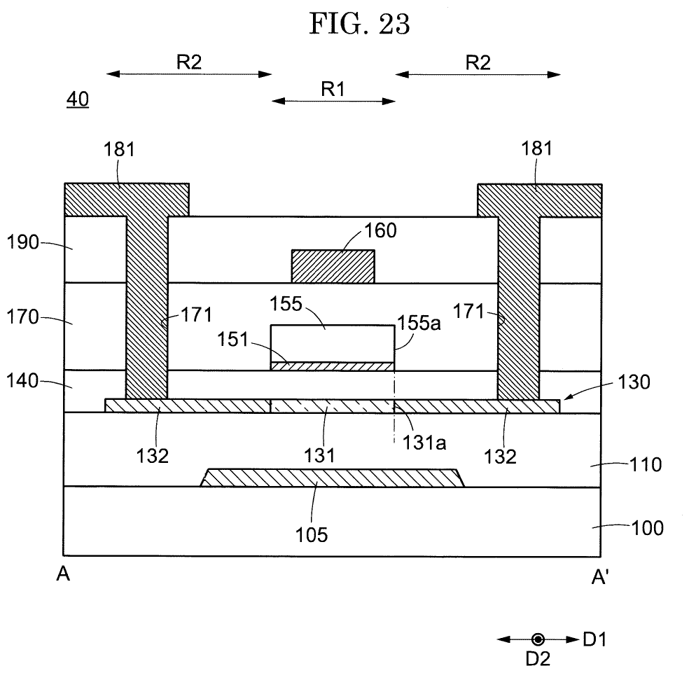

FIG. 23 is a schematic cross-sectional view showing a configuration of the semiconductor device 40 according to an embodiment of the present invention. The semiconductor device 40 shown in FIG. 23 is different from the semiconductor device 10 shown in FIG. 1 in that a patterned insulating layer 155 is provided on the metal oxide layer 151.

The insulating layer 155 is provided on the metal oxide layer 151. That is, the metal oxide layer 151 is provided between the insulating layer 140 and the insulating layer 155. The insulating layer 155 is processed into an island shape by patterning the insulating layer such as silicon oxide. The insulating layer 155 functions as a barrier layer that suppresses impurity ions implanted from above from reaching the channel portion 131 of the oxide semiconductor layer 130. For example, in the case where an insulating layer containing a large amount of oxygen or an insulating layer containing a large amount of defects is used as the insulating layer forming the insulating layer 155, the oxygen or defects function as hydrogen traps.

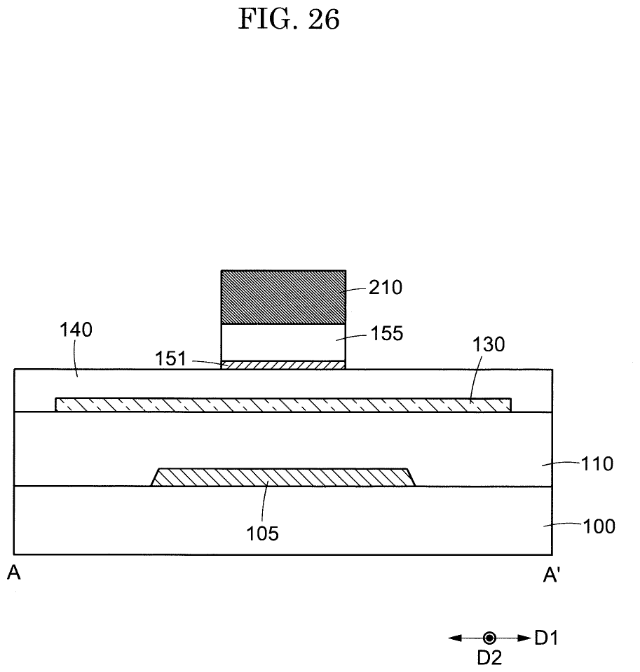

In the present embodiment, since the metal oxide layer 151 is formed using the resist mask 210 (see FIG. 26) used when the insulating layer 155 is patterned, the metal oxide layer 151 and the insulating layer 155 have the same pattern shape. That is, similar to the metal oxide layer 151, the insulating layer 155 overlaps the channel portion 131 of the oxide semiconductor layer 130. More specifically, as shown in FIG. 23 using a dash-dot line, in a cross-sectional view, a position of an edge 155a of the insulating layer 155 and the position of the edge 131a of the channel portion 131 are coincident in the vertical direction. In other words, in a cross-sectional view, the position of the edge 155a of the insulating layer 155 and the position of the boundary between the channel portion 131 and the conductive portion 132 are coincident in the vertical direction. The insulating layer 155 may be referred to as a “fourth gate insulating layer.” Although details will be described later, since the impurity ion is implanted after the insulating layer 155 is patterned, the insulating layer 155 contains the impurity.

The insulating layer 155 includes an insulating oxide. Specifically, silicon oxide (SiOₓ), silicon oxynitride (SiOₓN_{y}), aluminum oxide (AlOₓ), aluminum oxynitride (AlOₓN_{y}), or the like is used as the insulating layer 155. In the present embodiment, a silicon oxide layer having a thickness of 100 nm or more and 400 nm or less (preferably 100 nm or more and 300 nm or less, more preferably 150 nm or more and 250 nm or less) is used as the insulating layer 155. The insulating layer 155 functions as a blocking layer that suppresses the impurity from being implanted into the channel portion 131 when the impurity is added to the oxide semiconductor layer 130.

Other advantages of the semiconductor device 40 of the present embodiment are similar to those of the semiconductor device 10 of the first embodiment.

### 4-2. Method for Manufacturing Semiconductor Device

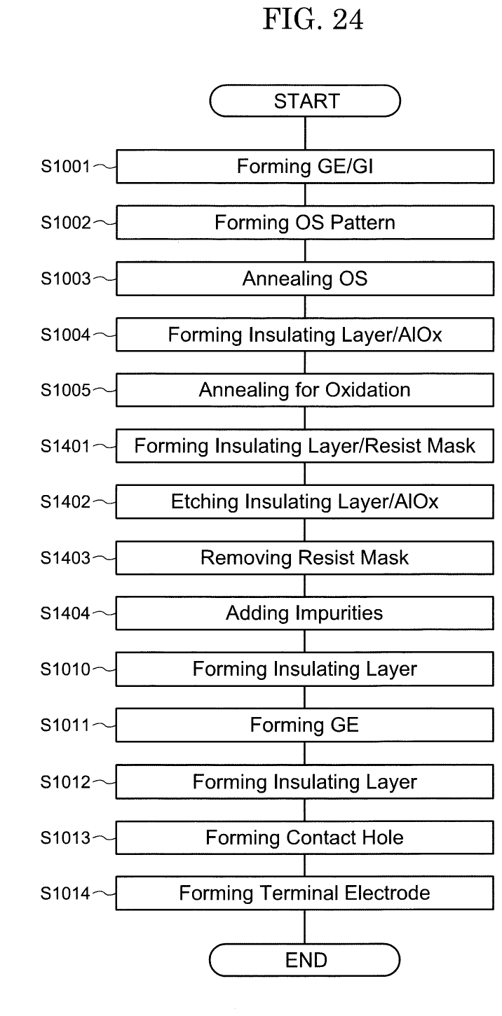

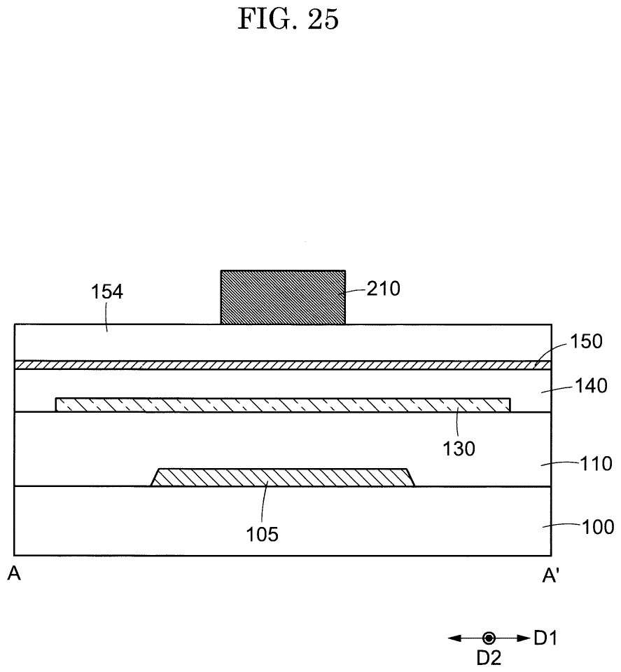

Next, a method for manufacturing the semiconductor device 40 according to an embodiment of the present invention will be described. FIG. 24 is a sequence diagram showing the method for manufacturing the semiconductor device 40 according to an embodiment of the present invention. FIG. 25 to FIG. 28 are schematic cross-sectional views showing the method for manufacturing the semiconductor device 40 according to an embodiment of the present invention.

In the method for manufacturing the semiconductor device 40 of the present embodiment, step S1001 to step S1005 shown in FIG. 24 are the same as step S1001 to step S1005 shown in FIG. 3 of the first embodiment. The manufacturing method of the present embodiment is different from the manufacturing method of the first embodiment in that step S1401 to step S1404 shown in FIG. 24 are performed instead of step S1006 to step S1009 shown in FIG. 3.

First, similar to the first embodiment, oxygen is supplied to the oxide semiconductor layer 130 in a state where the metal oxide layer 150 is formed, through step S1001 to step S1005 in FIG. 3. Next, as shown in FIG. 24 and FIG. 25, an insulating layer 154 is formed on the metal oxide layer 150, and the resist mask 210 is formed on the insulating layer 154 (step S1401 in FIG. 24). A silicon oxynitride (SiOₓN_{y}) layer is used as the insulating layer 154 of the present embodiment.

Since the insulating layer 154 is a silicon oxynitride layer, the insulating layer 154 contains a relatively large amount of oxygen by setting the deposition temperature to be relatively low. Since the amount of oxygen contained in the insulating layer 154 increases, a sufficient amount of oxygen can be supplied to the oxide semiconductor layer 130 during the oxidation annealing process, and the diffusion of hydrogen into the oxide semiconductor layer 130 from above can be effectively suppressed. The deposition temperature of the insulating layer 154 is set to 250° C. or higher and 500° C. or lower (preferably 300° C. or higher and 450° C. or lower, and more preferably 325° C. or higher and 400° C. or lower).

The resist mask 210 is arranged to overlap the oxide semiconductor layer 130. As will be described later, a portion of the oxide semiconductor layer 130 that overlaps the resist mask 210 corresponds to a portion where the channel portion 131 is formed. As shown in FIG. 2, the resist mask 210 is arranged to intersect the oxide semiconductor layer 130 in the second direction.

Next, as shown in FIG. 24 and FIG. 26, by etching the metal oxide layer 150 and the insulating layer 154 using the resist mask 210 as a mask, the metal oxide layer 151 and the insulating layer 155 are formed (step S1402 in FIG. 24). The etching of the metal oxide layer 150 and the insulating layer 154 may be wet etching or dry etching. For example, dilute hydrofluoric acid (DHF) is used as the wet

### Etching.

When the insulating layer 154 is etched, the selectivity between the metal oxide layer 150 and the insulating layer 154 is preferably high. If the selectivity is high, the metal oxide layer 150 can be used as an etching stopper when etching the insulating layer 154. In this case, after the insulating layer 154 is etched, the etchant or etching gas is changed to etch the oxide layer 150. The selectivity between the insulating layer 140 and the metal oxide layer 150 is preferably high with respect to the etching conditions for the metal oxide layer 150.

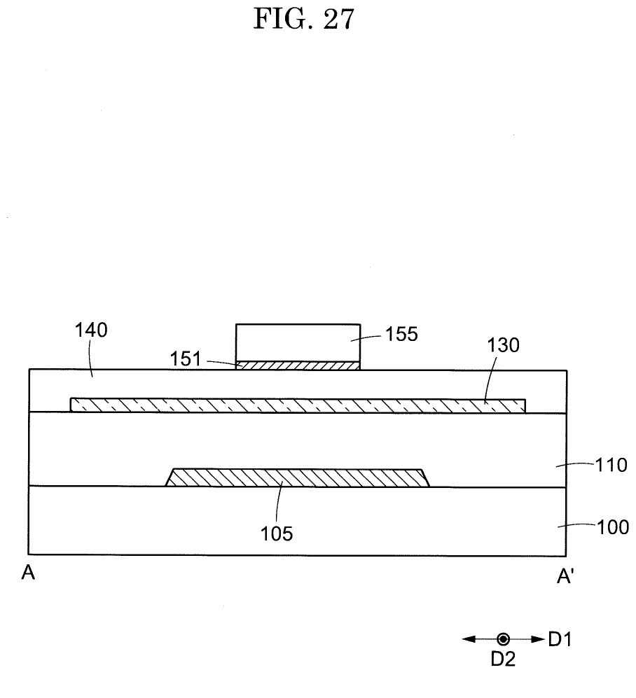

Next, as shown in FIG. 24 and FIG. 27, the resist mask 210 is removed (step S1403 in FIG. 24). By removing the resist mask 210, the metal oxide layer 151 and the insulating layer 155 remain on the insulating layer 140.

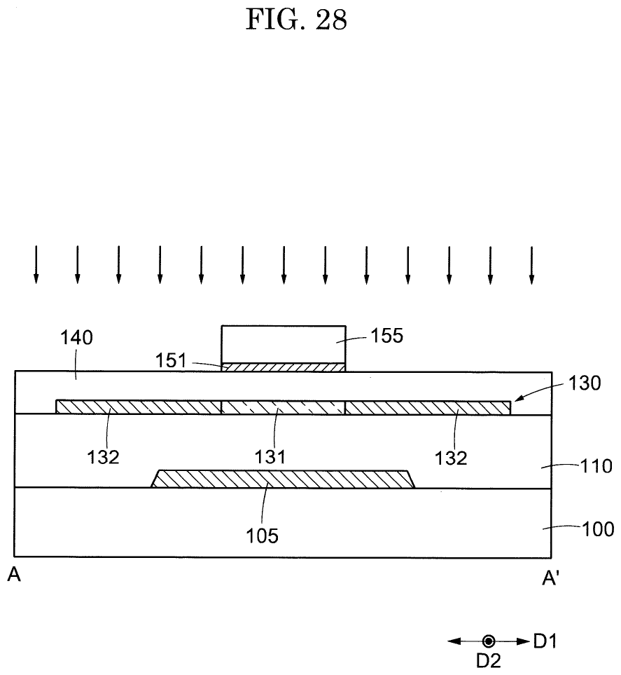

Next, as shown in FIG. 24 and FIG. 28, ions are implanted from above the insulating layer 155, and an impurity is added to the oxide semiconductor layer 130 (step S1404 in FIG. 24). Phosphorus, boron, argon, or the like is used as the impurity. The purpose of adding the impurity is to increase conductivity by forming oxygen vacancies in a partial region of the oxide semiconductor layer 130. Therefore, an element having a large atomic radius is preferably used as the impurity. In the present embodiment, although an example in which the impurity is added by ion implantation is shown, the impurity may be added by ion doping. In the present embodiment, boron is added by ion implantation. Conditions of the ion implantation process of the present embodiment are the acceleration voltage of 30 keV and the dose amount of 1×10¹⁵/cm², but are not limited to this example.

After the conductive portion 132 is formed through the processes described above, the semiconductor device 40 shown in FIG. 23 is completed through step S1010 to step S1014 shown in FIG. 24. Step S1010 to step S1014 shown in FIG. 24 are the same as step S1010 to step S1014 shown in FIG. 3 of the first embodiment.

### 4-3. First Modification of Fourth Embodiment

In the semiconductor device 40 described above, although an example in which the metal oxide layer 150 is etched to form the patterned metal oxide layer 151 has been shown, the metal oxide layer 150 may remain without being patterned.

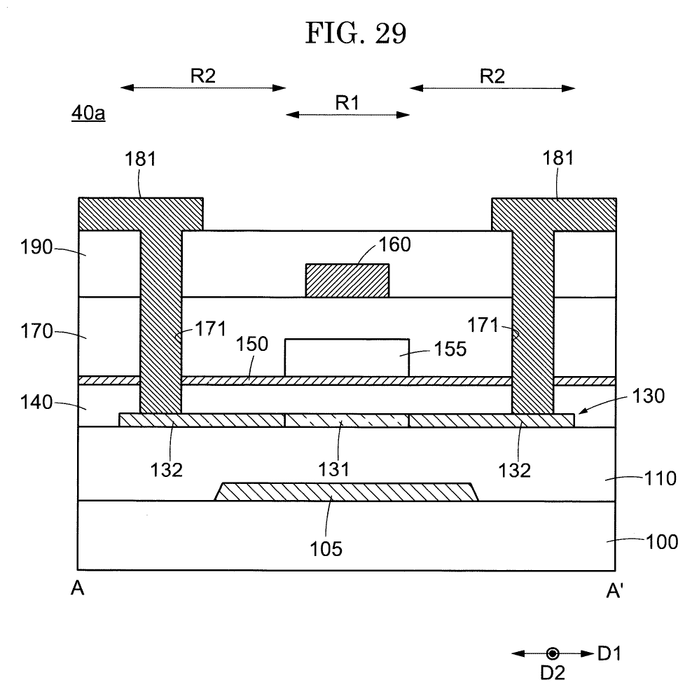

FIG. 29 is a schematic cross-sectional view showing a configuration of a semiconductor device 40a according to a modification of an embodiment of the present invention. In the semiconductor device 40a of the present modification, the metal oxide layer 150 is not patterned and remains on the insulating layer 140. That is, the metal oxide layer 150 overlaps the conductive portion 132 in addition to the channel portion 131 of the oxide semiconductor layer 130 in a plan view. In other words, the metal oxide layer 150 is provided not only between the insulating layer 140 and the insulating layer 155 in the first region R1, but also between the insulating layer 140 and the insulating layer 170 in the second region R2.

In the semiconductor device 40a of the present modification, similar to the metal oxide layer 151 shown in FIG. 23, the metal oxide layer 150 functions as a barrier layer that suppresses hydrogen diffused from above from reaching the oxide semiconductor layer 130.

### 4-4. Second Modification of Fourth Embodiment

In the semiconductor device 40 described above, although an example in which the metal oxide layer 150 is etched to form the patterned metal oxide layer 151, the metal oxide layer 150 may be removed by etching without being patterned.

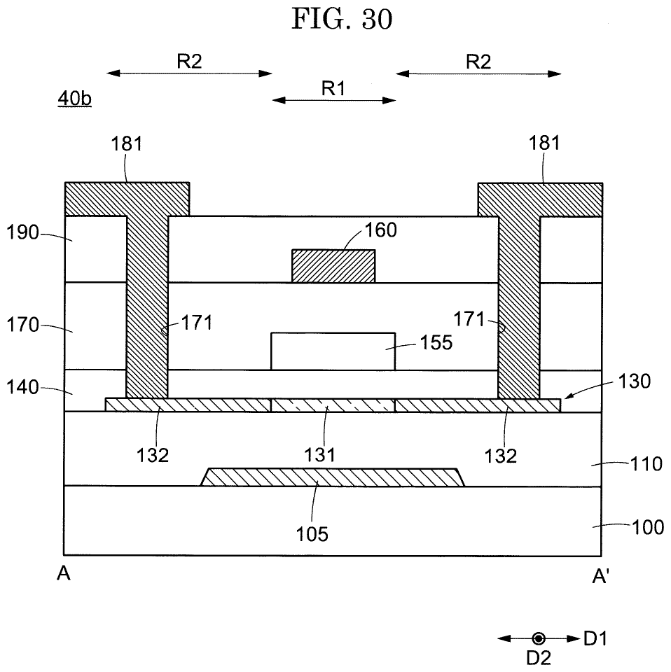

FIG. 30 is a schematic cross-sectional view showing a configuration of a semiconductor device 40b according to a modification of an embodiment of the present invention. The semiconductor device 40b is provided with a step of completely removing the metal oxide layer 150 formed on the insulating layer 140 by etching after the oxidation annealing process shown in step S1005 in FIG. 24. That is, in the present modification, neither the metal oxide layer 151 shown in FIG. 23 nor the metal oxide layer 150 shown in FIG. 29 is present on the insulating layer 140.

According to the present modification, in the process of adding impurities to the oxide semiconductor layer 130 shown in S1404 in FIG. 24, the dose amount of impurities to be added can be sufficiently increased even if the acceleration voltage is set low. According to the present modification, the contact hole 171 can be easily formed in the insulating layers 140, 170, and 190 shown in S1013 in FIG. 24.

### 5. Fifth Embodiment

In the present embodiment, a semiconductor device 50 in which the configuration of the oxide semiconductor layer 130 is different from that of the semiconductor device 40 of the fourth embodiment will be described. In the description of the present embodiment, the same reference signs are used to denote the same elements as those of the fourth embodiment, and the description thereof may be omitted.

### 5-1. Configuration of Semiconductor Device

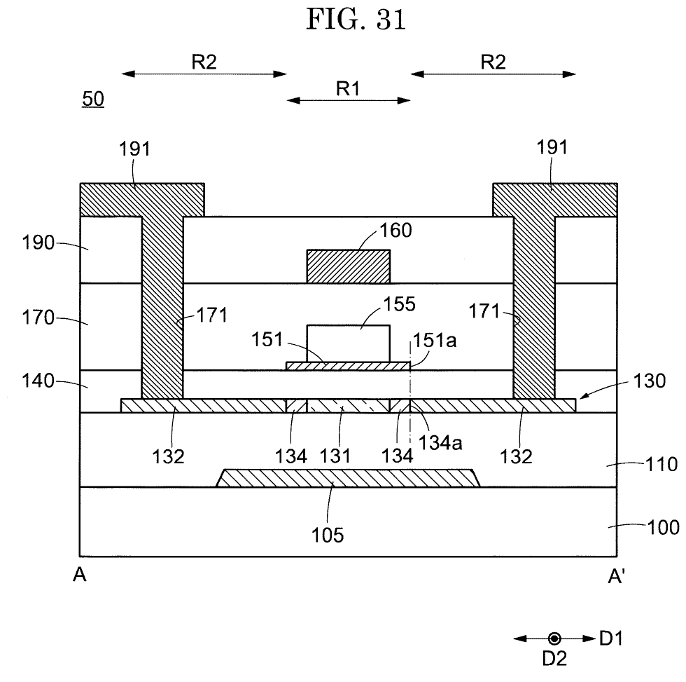

FIG. 31 is a schematic cross-sectional view showing a configuration of the semiconductor device 50 according to an embodiment of the present invention. The difference from the semiconductor device 40 shown in FIG. 23 is that the LDD portion 134 is provided in the oxide semiconductor layer 130. As shown in FIG. 31, the LDD portion 134 is arranged between the channel portion 131 and the conductive portion 132. In other words, the oxide semiconductor layer 130 of the present embodiment has a structure in which the channel portion 131, the LDD portion 134, and the conductive portion 132 are contiguous in the direction D1.

The metal oxide layer 151 composed of a metal oxide overlaps the channel portion 131 and the LDD portion 134. In the present embodiment, in a cross-sectional view, the position of the edge 151a of the metal oxide layer 151 and the position of the edge 134a of the LDD portion 134 are coincident in the vertical direction. In other words, in a cross-sectional view, the position of the edge 151a of the metal oxide layer 151 and the position of the boundary between the LDD portion 134 and the conductive portion 132 are coincident in the vertical direction. As described above, in the present embodiment, since the width of the metal oxide layer 151 is wider than the width of the channel portion 131 in the direction D1, it is effective in effectively utilizing the function of the metal oxide layer 151 (the function of suppressing the hydrogen diffused from above from reaching the channel portion 131 of the oxide semiconductor layer 130). However, the present invention is not limited to this configuration, and the metal oxide layer 151 may not overlap the LDD portion 134.

Other advantages of the semiconductor device 50 of the present embodiment are similar to those of the semiconductor device 40 of the fourth embodiment.

### 5-2. Method for Manufacturing Semiconductor Device

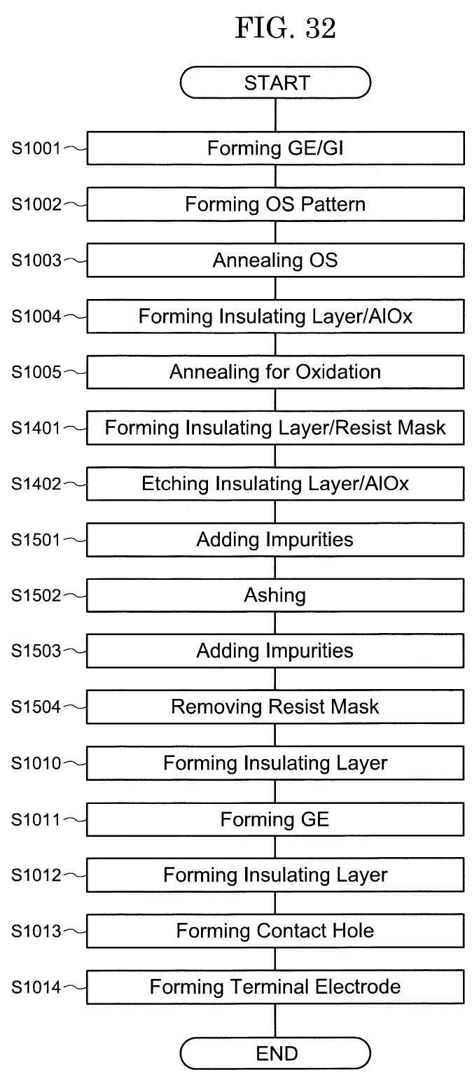

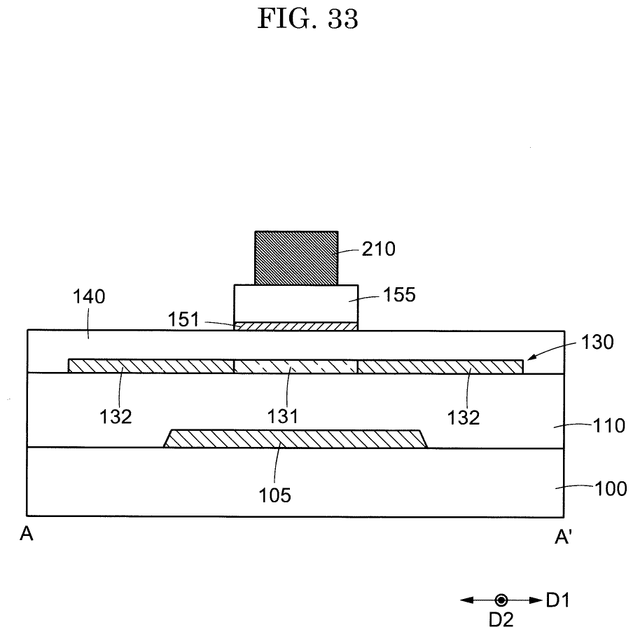

Next, a method for manufacturing the semiconductor device 50 according to an embodiment of the present invention will be described. FIG. 32 is a sequence diagram showing the method for manufacturing the semiconductor device 50 according to an embodiment of the present invention. FIG. 33 to FIG. 35 are schematic cross-sectional views showing the method for manufacturing the semiconductor device 50 according to an embodiment of the present invention.

In the method for manufacturing the semiconductor device 50 of the present embodiment, step S1001 to step S1005 and step S1401 to step S1402 shown in FIG. 32 are the same as step S1001 to step S1005 and step S1401 to step S1402 shown in FIG. 24 of the fourth embodiment. The manufacturing method of the present embodiment is different from the manufacturing method of the fourth embodiment in that step S1501 to step S1504 shown in FIG. 32 are performed instead of step S1403 to step S1404 shown in FIG. 24.

First, similar to the fourth embodiment, by etching the metal oxide layer 150 and the insulating layer 154 using the resist mask 210 as a mask, the metal oxide layer 151 and the insulating layer 155 are formed through step S1001 to step S1005 and step S1401 to step S1402 in FIG. 24, as shown in FIG. 26. In the present embodiment, the conductive portion 132 is formed by adding impurities to the oxide semiconductor layer 130 in this state (step S1501 in FIG. 32). Conditions of the ion implantation process in step S1501 may be the same as or different from step S1404 in FIG. 24. In the present embodiment, similar to step S1404, the acceleration voltage is 30 keV and the dose amount is 1×10¹⁵/cm².

After the conductive portion 132 is formed, as shown in FIG. 32 and FIG. 33, an ashing treatment is performed on the resist mask 210 in an oxidizing atmosphere (step S1502 in FIG. 32). By performing the ashing treatment, the width of the resist mask 210 in the direction D1 is narrowed.

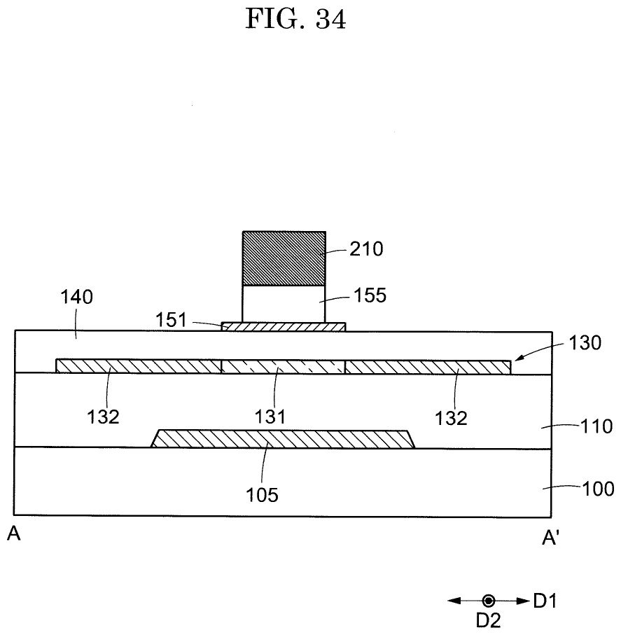

Next, as shown in FIG. 32 and FIG. 34, the insulating layer 155 is etched via the resist mask 210. The etching of the insulating layer 155 may be wet etching or dry etching. By etching the insulating layer 155, a portion of the upper surface of the metal oxide layer 151 is exposed.

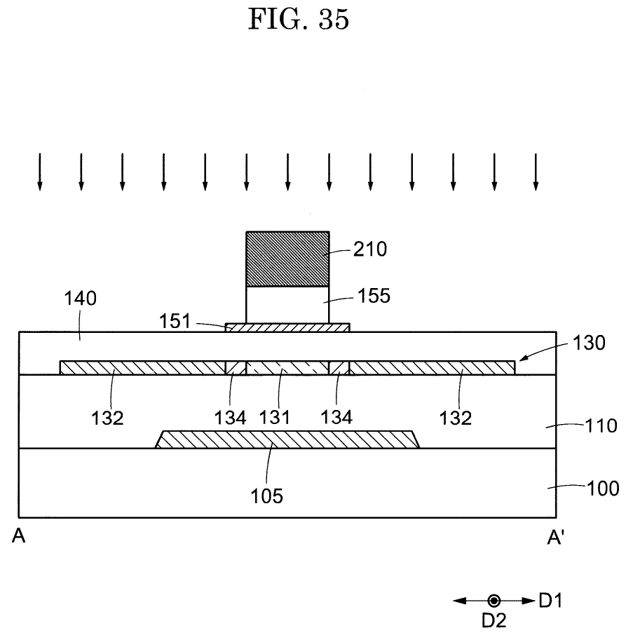

Next, as shown in FIG. 32 and FIG. 35, ions are implanted from above the resist mask 210, and the second impurity is added to the oxide semiconductor layer 130 (step S1503 in FIG. 32). The impurities to be added are the same as those used in the impurity addition in step S1501 in FIG. 32 (phosphorus, boron, argon, or the like).

Conditions of the ion implantation process may be the same as or different from step S1501 in FIG. 32. In the present embodiment, similar to step S1501, the acceleration voltage is 30 keV and the dose amount is 1×10¹⁵/cm². As shown in FIG. 35, in the present embodiment, the LDD portion 134 is formed at the end portions (portions not overlapping the resist mask 210) of the channel portion 131 in the direction D1 by the second impurity addition. In this case, since the impurities are added to the LDD portion 134 via the metal oxide layer 151 and the insulating layer 140, the amount of impurities to be added is smaller than that of the conductive portion 132 even if the impurities are added under the same conditions as in step S1501. That is, the resistance value of the LDD portion 134 is higher than the resistance value of the conductive portion 132.

After the LDD portion 134 is formed through the processes described above, the semiconductor device 50 shown in FIG. 31 is completed through step S1010 to step S1014 shown in FIG. 32. Step S1010 to step S1014 shown in FIG. 32 are the same as step S1010 to step S1014 shown in FIG. 24 of the fourth embodiment.

### 6. Sixth Embodiment

In the present embodiment, a display device 500 using the semiconductor device 10 according to an embodiment of the present invention will be described. In the embodiment described below, a configuration in which the semiconductor device 10 described in the first embodiment is used as an element constituting a circuit of the liquid crystal display device will be described. However, the present invention is not limited to this example, and the semiconductor devices described in the second to fifth embodiments may be used as the element constituting the circuit of the liquid crystal display device. The semiconductor device may be used as an element constituting a circuit of other display devices, such as an organic EL display device, instead of the element constituting the circuit of the liquid crystal display device.

### 6-1. Overview of Display Device

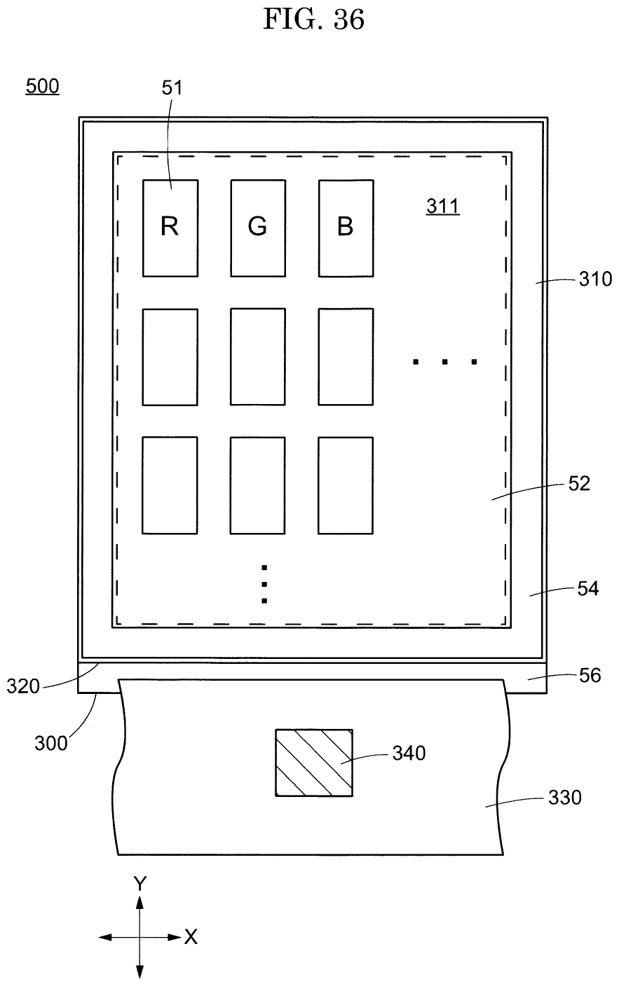

FIG. 36 is a schematic plan view showing an overall configuration of the display device 500 according to an embodiment of the present invention. As shown in FIG. 36, the display device 500 includes an array substrate 300, a seal portion 310, a counter substrate 320, a flexible printed circuit (FPC) board 330, and an IC chip 340. The array substrate 300 and the counter substrate 320 are bonded together by the seal portion 310. In a liquid crystal region 52 surrounded by the seal portion 310, a plurality of pixels 51 is arranged in a matrix. That is, a display region is formed of the plurality of pixels 51 arranged side by side in the direction X and the direction Y, respectively. The liquid crystal region 52 is a region that overlaps a liquid crystal element 311 described later in a plan view. With respect to the pixel 51, the letters “R,” “G,” and “B” indicate that the letters correspond to a pixel for red display, a pixel for green display, and a pixel for blue display, respectively.

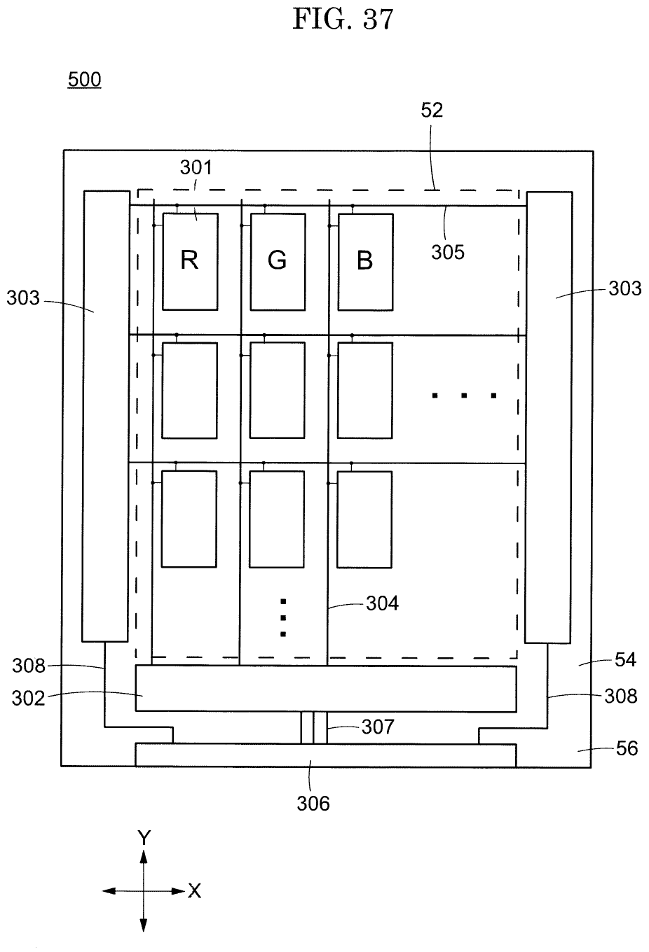

A seal region 54 where the seal portion 310 is provided is a region surrounding the liquid crystal region 52. The flexible printed circuit board 330 is provided in a terminal region 56. The terminal region 56 is a region of the array substrate 300 exposed from the counter substrate 320, and is provided outside the seal region 54. The outside of the seal region 54 means the outside of the region where the seal portion 310 is provided and the region surrounded by the seal portion 310. The IC chip 340 is provided on the flexible printed circuit board 330. The IC chip 340 supplies a signal for driving each pixel circuit 301 (see FIG. 37) arranged in each pixel 51.

### 6-2. Circuit Configuration of Display Device

FIG. 37 is a block diagram showing a circuit configuration of the display device 500 according to an embodiment of the present invention. As shown in FIG. 37, a plurality of pixel circuits 301 is arranged in a matrix corresponding to each pixel 51 shown in FIG. 36. A source driver circuit 302 is provided at a position adjacent to the liquid crystal region 52 in which the pixel circuit 301 is arranged in the direction Y (column direction). A gate driver circuit 303 is provided at a position adjacent to the liquid crystal region 52 in the direction X (row direction). The source driver circuit 302 and the gate driver circuit 303 are provided in the seal region 54. However, the region where the source driver circuit 302 and the gate driver circuit 303 are provided is not limited to the seal region 54, and may be outside the region where the pixel circuit 301 is provided.

A data signal line 304 extends from the source driver circuit 302 in the direction Y and is connected to the plurality of pixel circuits 301 arranged in the direction Y. A scanning signal line 305 extends from the gate driver circuit 303 in the direction X and is connected to the plurality of pixel circuits 301 arranged in the direction X.

A terminal portion 306 is provided in the terminal region 56. The terminal portion 306 and the source driver circuit 302 are connected by a connection wiring 307. Similarly, the terminal portion 306 and the gate driver circuit 303 are connected by a connection wiring 308. When the flexible printed circuit board 330 is connected to the terminal portion 306, an external device and the display device 500 are connected via the flexible printed circuit board 330. Each pixel circuit 301 provided in the display device 500 is driven by a signal from an external device input via the flexible printed circuit board 330.

The semiconductor device 10 described in the first embodiment is used as a switching element or a current control element included in the pixel circuit 301, the source driver circuit 302, and the gate driver circuit 303.

### 6-3. Pixel Circuit of Display Device

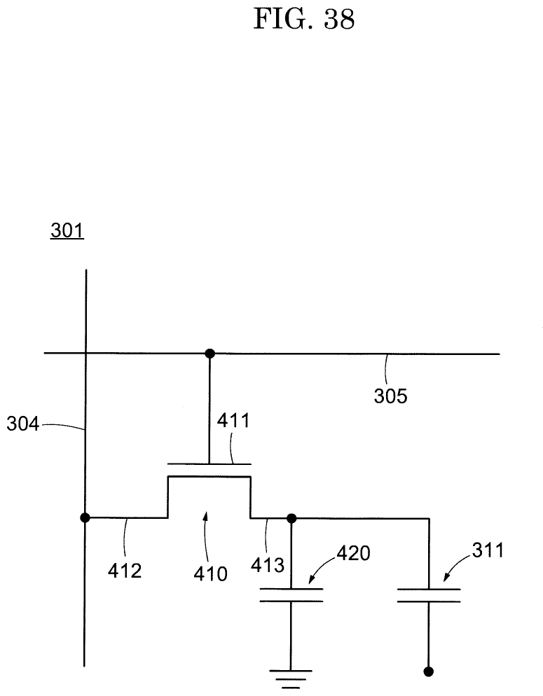

FIG. 38 is a circuit diagram showing a configuration of the pixel circuit 301 of the display device 500 according to an embodiment of the present invention. As shown in FIG. 38, the pixel circuit 301 includes elements such as a switching element 410, a storage capacitor 420, and the liquid crystal element 311.

The switching element 410 is implemented by the semiconductor device 10 of the first embodiment. The switching element 410 includes a gate electrode 411, a source electrode 412, and a drain electrode 413. The gate electrode 411 is connected to the scanning signal line 305. However, the gate electrode 411 and the scanning signal line 305 may be formed of an integral conductive layer. The source electrode 412 is connected to the data signal line 304. However, the source electrode 412 and the data signal line 304 may be formed of an integral conductive layer.

The drain electrode 413 is connected to the storage capacitor 420 and the liquid crystal element 311. The roles of the source electrode 412 and the drain electrode 413 may be reversed depending on the relationship between a voltage supplied to the data signal line 304 and a voltage stored in the storage capacitor 420. That is, the source electrode 412 may function as a drain electrode, and the drain electrode 413 may function as a source electrode.

### 6-4. Pixel Structure of Display Device

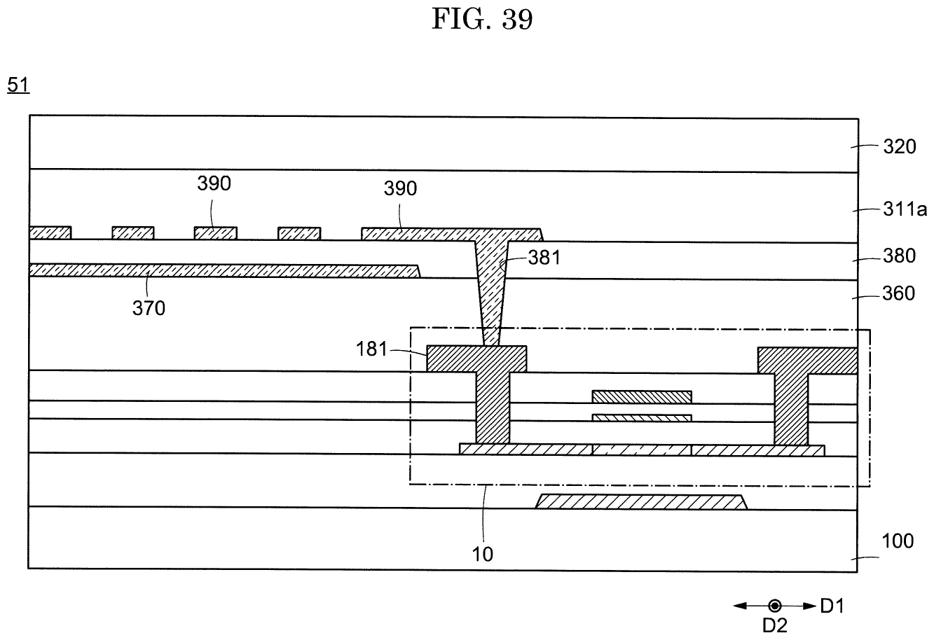

FIG. 39 is a cross-sectional view showing a pixel structure of the display device 500 according to an embodiment of the present invention. In the display device 500, the semiconductor device 10 described in the first embodiment is used as the switching element 410 included in the pixel circuit 301. In the following description, since the configuration of the semiconductor device 10 is the same as that of the semiconductor device 10 shown in FIG. 1, detailed description thereof will be omitted.

An insulating layer 360 is provided on the terminal electrode 181 of the semiconductor device 10. For example, an acrylic resin is used as the insulating layer 360. A common electrode 370 provided on the insulating layer 360 in common to a plurality of pixels is provided. An insulating layer 380 is provided on the common electrode 370. For example, a silicon nitride layer is used as the insulating layer 380. A contact hole 381 is provided in the insulating layers 360 and 380. A pixel electrode 390 connected to the terminal electrode 181 via the contact hole 381 is provided on the insulating layer 380.

A transparent conductive layer is used as the common electrode 370 and the pixel electrode 390. In the present embodiment, although an ITO (Indium Tin Oxide) is used as the material of the transparent conductive layer forming the common electrode 370 and the pixel electrode 390, other metal oxide layers may be used. The common electrode 370 is composed of a plate-like transparent conductive layer. Although not shown in FIG. 39, the pixel electrode 390 is composed of a comb-shaped transparent conductive layer in which a portion extending in the direction D1 and a portion extending in the direction D2 are combined. The portion extending in the direction D2 is composed of a plurality of linear electrodes, and is connected to an electrode corresponding to a trunk extending in the direction D1.

A liquid crystal layer 311a is sealed between an active matrix substrate formed on the substrate 100 to the pixel electrode 390 and the counter substrate 320. The liquid crystal layer 311a is arranged across the plurality of pixels 51. The region where the liquid crystal layer 311a is arranged corresponds to the liquid crystal region 52 shown in FIG. 36.

As shown in FIG. 39, the common electrode 370 has an overlapping region overlapping the pixel electrode 390 in a plan view and a non-overlapping region not overlapping the pixel electrode 390. When a voltage is supplied between the pixel electrode 390 and the common electrode 370, a lateral electric field is formed from the pixel electrode 390 in the overlapping region towards the common electrode 370 in the non-overlapping region. The liquid crystal molecules contained in the liquid crystal layer 311a are operated due to the lateral electric field, and the gradation of the light passing through the pixel 51 is determined.

Each of the embodiments described above (including the modifications of each embodiment) as the embodiment of the present invention can be appropriately combined as long as there is no contradiction. Further, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first gate electrode above an insulating surface;
a first gate insulating layer above the first gate electrode;
an oxide semiconductor layer above the first gate insulating layer and including a channel portion and a conductive portion having lower resistance than the channel portion;
a second gate insulating layer above the oxide semiconductor layer;
a third gate insulating layer above the second gate insulating layer; and
a second gate electrode above the third gate insulating layer,
wherein
the semiconductor device includes a first region overlapping the channel portion in a plan view and a second region overlapping the conductive portion in the plan view,
an amount of impurities included in the conductive portion is more than an amount of the impurities included in the channel portion,
the second gate insulating layer in the second region includes the impurities, and
the third gate insulating layer in the second region does not include the impurities.

2. The semiconductor device according to claim 1, further comprising a metal oxide layer between the second gate insulating layer and the third gate insulating layer and including aluminum.

3. The semiconductor device according to claim 2, wherein the metal oxide layer is provided in both the first region and the second region.

4. The semiconductor device according to claim 2, wherein a position of an edge of the metal oxide layer and a position of an edge of the channel portion are coincident in a vertical direction in a cross-sectional view.

5. The semiconductor device according to claim 1, further comprising a fourth gate insulating layer between the second gate insulating layer and the third gate insulating layer,
wherein a position of an edge of the fourth gate insulating layer and a position of an edge of the channel portion are coincident in a vertical direction in a cross-sectional view.

6. The semiconductor device according to claim 5, wherein the fourth gate insulating layer includes the impurities.

7. The semiconductor device according to claim 5, further comprising a metal oxide layer between the second gate insulating layer and the fourth gate insulating layer and including aluminum.

8. The semiconductor device according to claim 7, wherein the metal oxide layer is provided between the second gate insulating layer and the fourth gate insulating layer in the second region.

9. A semiconductor device comprising:
a first gate electrode above an insulating surface;
a first gate insulating layer above the first gate electrode;
an oxide semiconductor layer above the first gate insulating layer and including a channel portion and a conductive portion having lower resistance than the channel portion;
a second gate insulating layer above the oxide semiconductor layer;
a third gate insulating layer above the second gate insulating layer; and
a second gate electrode above the third gate insulating layer,
wherein
the semiconductor device includes a first region overlapping the channel portion in a plan view and a second region overlapping the conductive portion in the plan view,
an amount of impurities included in the conductive portion is more than an amount of the impurities included in the channel portion, and
in the second region, an average concentration of the impurities in a thickness direction of the second gate insulating layer is 100 times or more than an average concentration of the impurities in the thickness direction of the third gate insulating layer.

10. The semiconductor device according to claim 9, further comprising a metal oxide layer between the second gate insulating layer and the third gate insulating layer and including aluminum.

11. The semiconductor device according to claim 10, wherein the metal oxide layer is provided in both the first region and the second region.

12. The semiconductor device according to claim 10, wherein a position of an edge of the metal oxide layer and a position of an edge of the channel portion are coincident in a vertical direction in a cross-sectional view.

13. The semiconductor device according to claim 9, further comprising a fourth gate insulating layer between the second gate insulating layer and the third gate insulating layer,
wherein a position of an edge of the fourth gate insulating layer and a position of an edge of the channel portion are coincident in a vertical direction in a cross-sectional view.

14. The semiconductor device according to claim 13, further comprising a metal oxide layer between the second gate insulating layer and the fourth gate insulating layer and including aluminum.

15. A semiconductor device comprising:
a first gate electrode above an insulating surface;
a first gate insulating layer above the first gate electrode;
an oxide semiconductor layer above the first gate insulating layer and including a channel portion and a conductive portion having lower resistance than the channel portion;
a second gate insulating layer above the oxide semiconductor layer;
a third gate insulating layer above the second gate insulating layer; and
a second gate electrode above the third gate insulating layer,
wherein
the semiconductor device includes a first region overlapping the channel portion in a plan view and a second region overlapping the conductive portion in the plan view,
an amount of impurities included in the conductive portion is more than an amount of the impurities included in the channel portion, and
in a vicinity of a boundary between the second gate insulating layer and the third gate insulating layer in the second region, a concentration of the impurities included in the second gate insulating layer is

100. times or more than a concentration of the impurities included in the third gate insulating layer.

16. The semiconductor device according to claim 15, further comprising a metal oxide layer between the second gate insulating layer and the third gate insulating layer and including aluminum.

17. The semiconductor device according to claim 16, wherein the metal oxide layer is provided in both the first region and the second region.

18. The semiconductor device according to claim 16, wherein a position of an edge of the metal oxide layer and a position of an edge of the channel portion are coincident in a vertical direction in a cross-sectional view.

19. The semiconductor device according to claim 15, further comprising a fourth gate insulating layer between the second gate insulating layer and the third gate insulating layer,
wherein a position of an edge of the fourth gate insulating layer and a position of an edge of the channel portion are coincident in a vertical direction in a cross-sectional view.

20. The semiconductor device according to claim 19, further comprising a metal oxide layer between the second gate insulating layer and the fourth gate insulating layer and including aluminum.
